(19) United States
(12) Patent Application Publication
(10) Pub. No.: US 2025/0192767 A1
(43) Pub. Date: Jun. 12, 2025

(54) LOW LEAKAGE CURRENT FEEDTHROUGH SWITCH

(71) Applicant: Kandou Labs SA, Saint-Sulpice (CH)

(72) Inventors: Mohammed Irfan Pakkada, Reading (GB); Guiseppe Surace, Lausanne (CH); Richard Simpson, Bedford (GB)

(21) Appl. No.: 19/047,800

(22) Filed: Feb. 7, 2025

Related U.S. Application Data
(60) Provisional application No. 63/607,392, filed on Dec. 7, 2023.
(60) Provisional application No. 63/676,510, filed on Jul. 29, 2024.

(51) Int. Cl. H03K 17/16

(52) U.S. Cl. CPC H03K 17/162

(57) ABSTRACT

A feedthrough switch that prevents, in a blocking mode, voltage signals from being transmitted via a feedthrough path, comprising a cascode circuit comprising two PMOS devices coupled in series. One of the PMOS devices is coupled to receive an input voltage signal at its source and the other coupled to a center node. A gate of each PMOS is biased using a biasing circuit including a voltage follower that provides a biasing voltage that tracks the input voltage signal up to a supply voltage of the voltage follower. The biasing voltage keeps both PMOS devices in a non-conductive state while the voltage signal is below the supply voltage. An overstress prevention voltage supply is coupled to the center node and maintains the center node at a fixed voltage to ensure that both PMOS devices remain within their respective rated voltages across the full range of the voltage signal.

### CROSS-REFERENCE TO RELATED APPLICATIONS

This application claims the benefit of U.S. Provisional Application No. 63/676,510, entitled “Low Leakage Current Feedthrough Switch”, filed Jul. 29, 2024, naming Mohammed Irfan Pakkada, and claims the benefit of U.S. Provisional Application No. 63/607,392, filed Dec. 7, 2023, naming “Low Leakage Current Feedthrough Switch”, naming Mohammed Irfan Pakkada, all of which are hereby incorporated by reference in their entirety for all purposes.

### REFERENCES

The following references are herein incorporated by reference in their entirety for all purposes:
Universal Serial Bus 3.2 Specification, Revision 1.1, June 2022, https://www [dot] usb [dot] org/document-library/usb-32-revision-11-june-2022.
Universal Serial Bus 4 Specification v2.0, 30 Jun. 2023, https://www [dot] usb [dot] org/document-library/usb4r-specification-v20.

### BACKGROUND

A common requirement in the design of electrical circuitry is a bypass circuit that allows a particular component or set of components to be bypassed. The bypass is usually only required some of the time, e.g. in certain operational modes, and therefore a switch is required to selectively turn the bypass on and off.

It is desirable for an open switch to prevent substantially all current from passing across the switch; that is, any ‘leakage current’ that passes across the switch when open is as low as possible.

A switch can be formed of one or more transistors (e.g. FETs). Transistors are designed to have a particular voltage differential range between pairs of legs, e.g. source and gate, over which range they have been tested to work correctly, often referred to as the ‘rated voltage’. It is desirable to ensure that, in normal operation, the rated voltage of a transistor is not exceeded whilst also maintaining a low leakage current.

This is complicated by the fact that it is common for transistors to be used in circuits that carry an AC voltage, meaning that the rated voltage is desirably not exceeded at any point in the AC waveform.

A further complication is that it is not always possible for a switch circuit to have control over signal voltage and/or supply voltage. For example, if a voltage signal originates within another device and is transmitted to the switch circuit, the voltage level of this signal will be set by this device and not the switch circuit. Similarly, the switch circuit may need to couple to a supply voltage that is provided by another device. A scenario in which this occurs is a USB retimer which is both powered by the device it is coupled to and also receives signals having a voltage set by the device it is coupled to.

It would thus be desirable to provide a switch circuit that has relatively low leakage current when off and that is also capable of preventing respective rating voltages of its constituent transistors from being exceeded during normal operation.

### BRIEF DESCRIPTION

An apparatus is provided that includes a feedthrough switch that prevents voltage signals from being transmitted via a feedthrough path in which the feedthrough switch is located when the feedthrough switch is operating in a blocking mode. The feedthrough switch comprises a cascode circuit comprising two p-channel metal-oxide semiconductor (PMOS) devices coupled in series, with one of these PMOS devices coupled to receive an input voltage signal at its source and the other coupled to a center node. A gate of each PMOS is biased using a biasing circuit that is also part of the feedthrough switch, the biasing circuit including a voltage follower that provides a biasing voltage that changes dynamically over time to track the input voltage signal up to a supply voltage of the voltage follower. The biasing voltage keeps both PMOS devices in a non-conductive state while the voltage signal is below the supply voltage. An overstress prevention voltage supply is coupled to the center node and maintains the center node at a fixed voltage to ensure that both PMOS devices remain within their respective rated voltages across the full range of the voltage signal. A bias current blocking circuit can also be present, the bias current blocking circuit configured to inhibit discharge of the gate input of the first PMOS device when the voltage signal exceeds the supply voltage.

In a first aspect, an embodiment provides an apparatus, comprising: two feedthrough switches coupled in a feedthrough path between a sideband use (SBU) input pin and a SBU output pin and configured, in a blocking mode, to prevent a sideband voltage signal from being transmitted between the SBU input pin and the SBU output pin via the feedthrough path, each feedthrough switch comprising: a cascode circuit comprising two PMOS devices connected in series between an input node and a center node, the input node coupled to a respective one of the SBU input pin and the SBU output pin and configured to receive the sideband voltage signal at a source of a first PMOS device of the two PMOS devices; a cascode PMOS biasing circuit comprising: a PMOS blocking voltage follower circuit coupled to a supply voltage and to the input node and configured to, in the blocking mode, provide first and second level-shifted bias voltages to gate inputs of the two PMOS devices, the level-shifted bias voltages tracking the sideband voltage signal according to a voltage offset to maintain the two PMOS devices in a non-conductive state while the sideband voltage signal is below the supply voltage; and an overstress prevention voltage supply configured to, in the blocking mode, bias the center node with a fixed voltage.

In a second aspect, an embodiment provides a method comprising: receiving, at one of a SBU input pin and a SBU output pin, a sideband voltage signal, the SBU input pin coupled to a SBU output pin via a feedthrough path; in a blocking mode, preventing the sideband voltage signal from being transmitted between the SBU input pin and the SBU output pin via the feedthrough path using two feedthrough switches that are each coupled in the feedthrough path between the SBU input pin and the SBU output pin, each feedthrough switch blocking the sideband voltage signal by: receiving the sideband voltage signal at a source of a first PMOS device that is part of a cascode circuit of the respective feedthrough switch, the cascode circuit comprising the first PMOS device and a second PMOS device connected in series between an input node and a center node, the input node coupled to one of the SBU input pin and the SBU output pin; biasing the cascode circuit by: providing, by a PMOS blocking voltage follower circuit of the respective feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage; and biasing the center node with a fixed voltage provided by an overstress prevention voltage supply.

In a third aspect, an embodiment provides an apparatus, comprising: a feedthrough switch coupled in a feedthrough path between a sideband use (SBU) input pin and a SBU output pin and configured, in a blocking mode, to prevent a sideband voltage signal from being transmitted between the SBU input pin and the SBU output pin via the feedthrough path, the feedthrough switch comprising: a cascode circuit comprising two PMOS devices connected in series between an input node and a center node, the input node coupled to a respective one of the SBU input pin and the SBU output pin and configured to receive the sideband voltage signal at a source of a first PMOS device of the two PMOS devices; a cascode PMOS biasing circuit comprising: a PMOS blocking voltage follower circuit coupled to a supply voltage and to the input node and configured to, in the blocking mode, provide first and second level-shifted bias voltages to gate inputs of the two PMOS devices, the level-shifted bias voltages tracking the sideband voltage signal according to a voltage offset to maintain the two PMOS devices in a non-conductive state while the sideband voltage signal is below the supply voltage; and an overstress prevention voltage supply configured to, in the blocking mode, bias the center node with a fixed voltage.

In a fourth aspect, an embodiment provides a method, comprising: receiving, at one of a SBU input pin and a SBU output pin, a sideband voltage signal, the SBU input pin coupled to a SBU output pin via a feedthrough path; in a blocking mode, preventing the sideband voltage signal from being transmitted between the SBU input pin and the SBU output pin via the feedthrough path using a feedthrough switch that is coupled in the feedthrough path between the SBU input pin and the SBU output pin, the feedthrough switch blocking the sideband voltage signal by: receiving the sideband voltage signal at a source of a first PMOS device that is part of a cascode circuit of the feedthrough switch, the cascode circuit comprising the first PMOS device and a second PMOS device connected in series between an input node and a center node, the input node coupled to one of the SBU input pin and the SBU output pin; biasing the cascode circuit by: providing, by a PMOS blocking voltage follower circuit of the feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage; and biasing the center node with a fixed voltage provided by an overstress prevention voltage supply.

### BRIEF DESCRIPTION OF FIGURES

FIG. 1 is a schematic drawing of a system comprising a retimer coupled between first and second devices, according to an embodiment.

FIG. 2 is a schematic drawing of the system of FIG. 1 providing more detail of various components.

FIG. 3 is a schematic drawing of the system of FIG. 1 providing further detail of the retimer that is part of this system.

FIGS. 4A and 4B together provide a circuit diagram of a pair of feedthrough switches, according to an embodiment.

FIG. 4C is a circuit diagram of the feedthrough switch of FIG. 4A showing only those components of the feedthrough switch that are active in a 3.3V blocking mode in which the feedthrough switch is disabled.

FIG. 4D is a circuit diagram of the feedthrough switch of FIG. 4A showing only those components of the feedthrough switch that are active in a 1.2V blocking mode in which the feedthrough switch is disabled.

FIG. 4E is a circuit diagram of the feedthrough switch of FIG. 4A showing only those components of the feedthrough switch that are active in a 3.3V passthrough mode in which the feedthrough switch is enabled.

FIG. 4F is a circuit diagram of the feedthrough switch of FIG. 4A showing only those components of the feedthrough switch that are active in a 1.2V passthrough mode in which the feedthrough switch is enabled.

FIG. 5 is a graph showing the variation of the gate voltage and gate to source voltage as a function of time of a PMOS device that is part of the feedthrough switch of FIG. 4A.

FIG. 6 is a graph showing the variation of the gate voltage and gate to source voltage as a function of time of a NMOS device that is part of the feedthrough switch of FIG. 4A.

FIG. 7 is a graph showing the variation of the resistance of the feedthrough switches shown in FIGS. 4A and 4B as a function of time, when operating in a passthrough mode in which the switches are enabled.

FIG. 8 is a graph showing the variation of various node and gate voltages as a function of time that are relevant to the feedthrough switch of FIG. 4A.

FIG. 9 is a flowchart setting out a method according to an embodiment.

FIG. 10 is a diagram of a feed through switch with an expanded input range, in accordance with some embodiments.

FIG. 11 is a schematic of one half of the feed-through switch of FIG. 10, in accordance with some embodiments.

FIG. 12 is a chart illustrating voltages at various nodes of the schematic of FIG. 11 for an input voltage sweep of 0 to 4.2V, in accordance with some embodiments.

FIG. 13 is a diagram for another feed through switch having an expanded input range, in accordance with some embodiments.

FIG. 14 is a diagram illustrating an output voltage Vout as a function of an input voltage Vin for a tracking circuit to further increase input voltage tolerance, in accordance with some embodiments.

FIG. 15 is a flowchart of a method, in accordance with some embodiments.

### DETAILED DESCRIPTION

The majority of this specification describes the operation of a feedthrough switch in the context of a sideband channel that is available between two communicating devices, and specifically as part of a retimer operating between these two devices. This context is provided to assist the reader in the understanding of embodiments. It should be understood that embodiments also have utility outside this context, specifically in any scenario in which it is desirable to have a low leakage switch with an input voltage that at least some of the time exceeds a rating of one or more transistors that are part of the switch. Embodiments also find utility in critical situations in which supply voltage is limited, particularly where a supply voltage maximum value is lower than an input voltage maximum value.

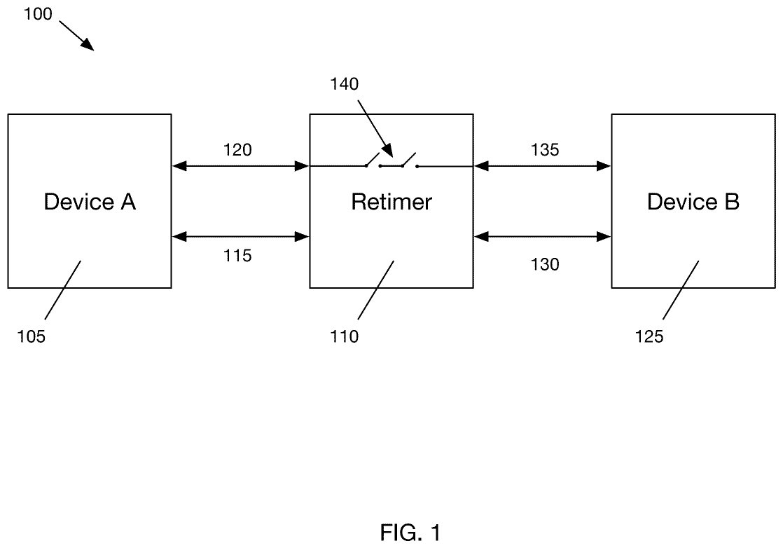

FIG. 1 is a schematic drawing of a system 100 in which the feedthrough switch described herein has utility, according to an embodiment. System 100 includes a first device 105 (‘Device A’) coupled to a retimer 110 via a first main channel 115 and a first sideband channel 120. Retimer 110 is also coupled to a second device 125 (′Device B′) via a second main channel 130 and a second sideband channel 135. The coupling in each case can be direct (e.g. circuit traces coupling to a system on chip that is part of first device 105 or second device 125) or via some intermediary such as a cable. Two feedthrough switches collectively labelled 140 in FIG. 1 are present within retimer 110 as part of the sideband channel.

It will be appreciated that many details have been omitted from FIG. 1 in the interests of clarity and as such FIG. 1 does not provide an exhaustive list of components present in system 100.

First device 105 can be any device, e.g. a host device. Second device 125 can also be any device, e.g. a peripheral device. The majority of communication between first device 105 and second device 125 takes place via first main channel 115 and second main channel 130. These main channels are high-speed and carry data. The protocol used can be any currently known protocol or a future developed protocol. Examples include Universal Serial Bus (USB) 3.x, USB 4.x, USB 4 v2, DisplayPort and Converged IO (CIO).

First sideband channel 120 and second sideband channel 135 carry sideband information that is communicated using a sideband voltage signal. The sideband voltage signal is a time-varying voltage signal, e.g. a time-varying digital signal having a LOW level and a HIGH level. In one particular embodiment, the LOW level is 0V and the HIGH level is 3.73V; these values are set by protocol specifications. These values are not limiting as other voltage levels can alternatively be used.

Sideband information includes commands, e.g. first device 105 may issue a command to retimer 110 or second device 125 to instruct the respective device to change a setting or provide some control information. Sideband information also includes control information, e.g. second device 125 might send control information relating to a current setting of second device 125 via first sideband channel 120 and second sideband channel 135. Retimer 110 can also issue commands and respond to issued commands via first sideband channel 120 or second sideband channel 135. In the case where retimer 110 receives sideband information destined for another device, retimer 110 forwards this sideband information on to the relevant device.

Retimer 110 is a device that receives an incoming signal and reconstructs it to improve signal to noise ratio, then transmits a ‘clean’ version of the signal onward. Retimers per se are known in the art and so a detailed account of this functionality is not provided here. For the purposes of this disclosure, it is sufficient to understand that retimer 110 is located between first device 105 and second device 125 in a signalling sense, such that data and sideband information exchanged between first device 105 and second device 125 is intercepted and retimed by retimer 110.

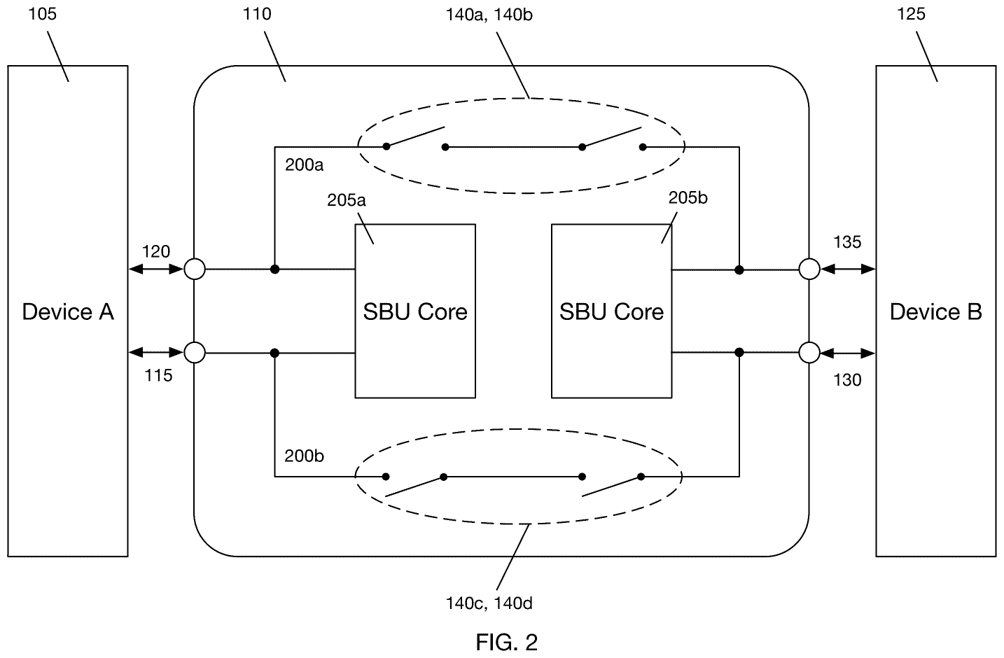

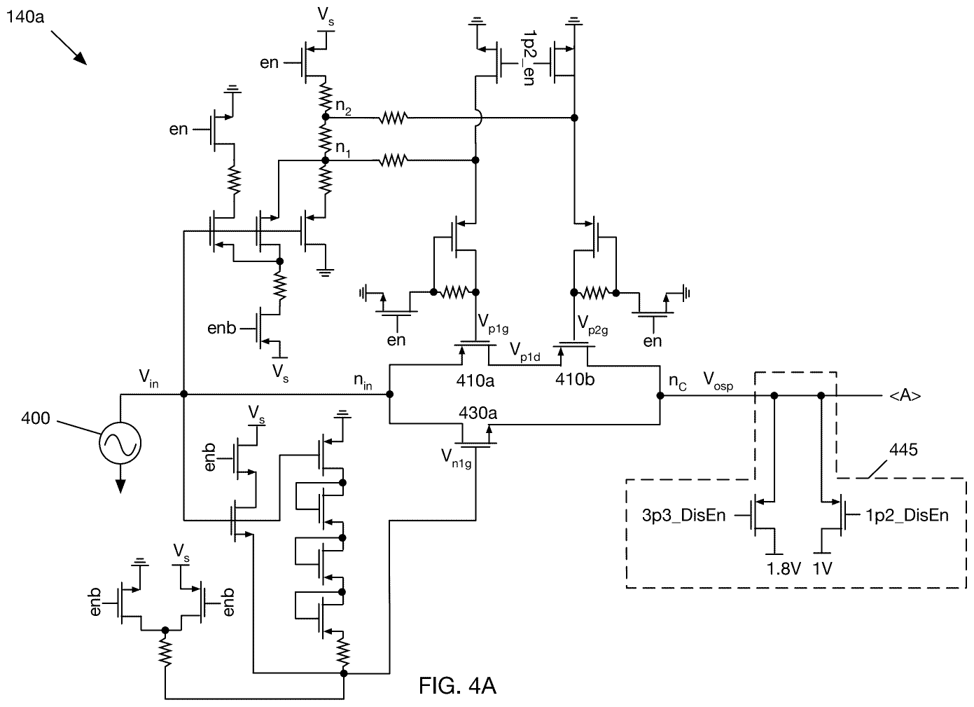

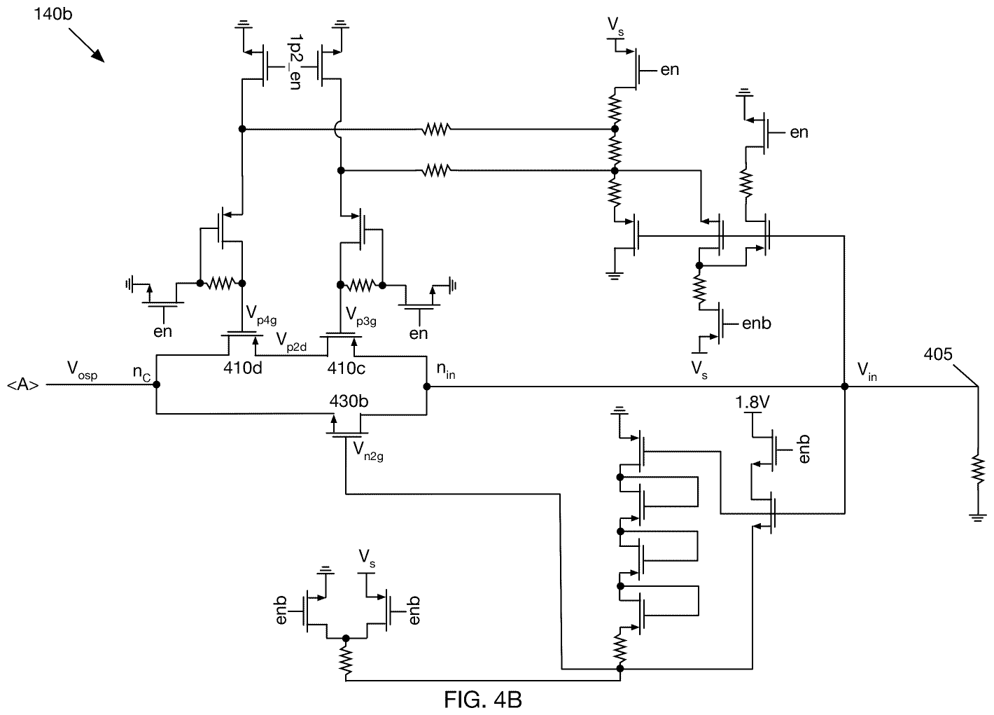

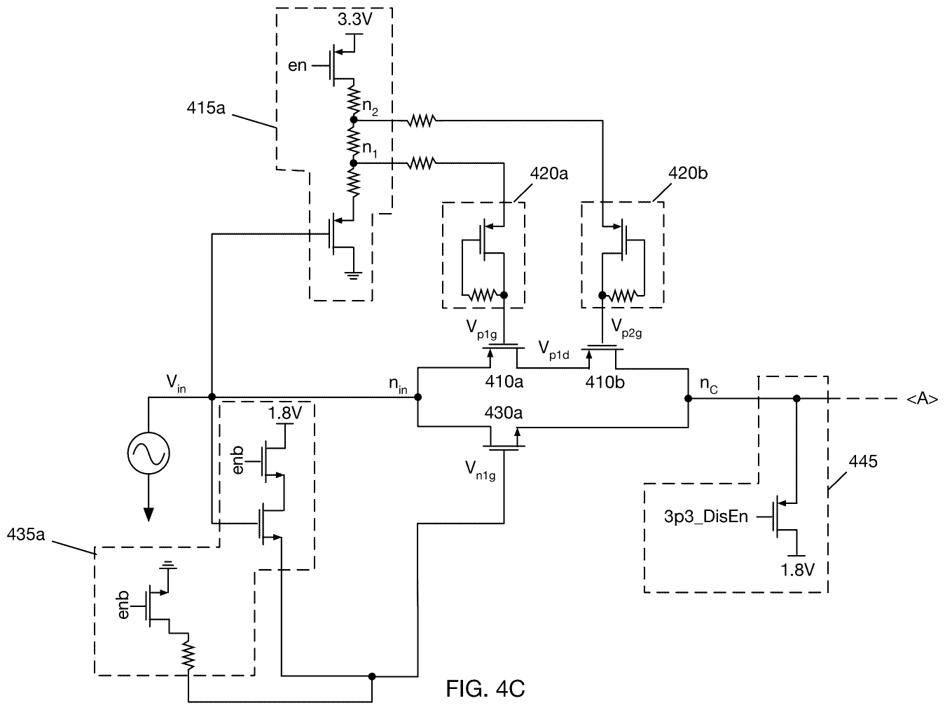

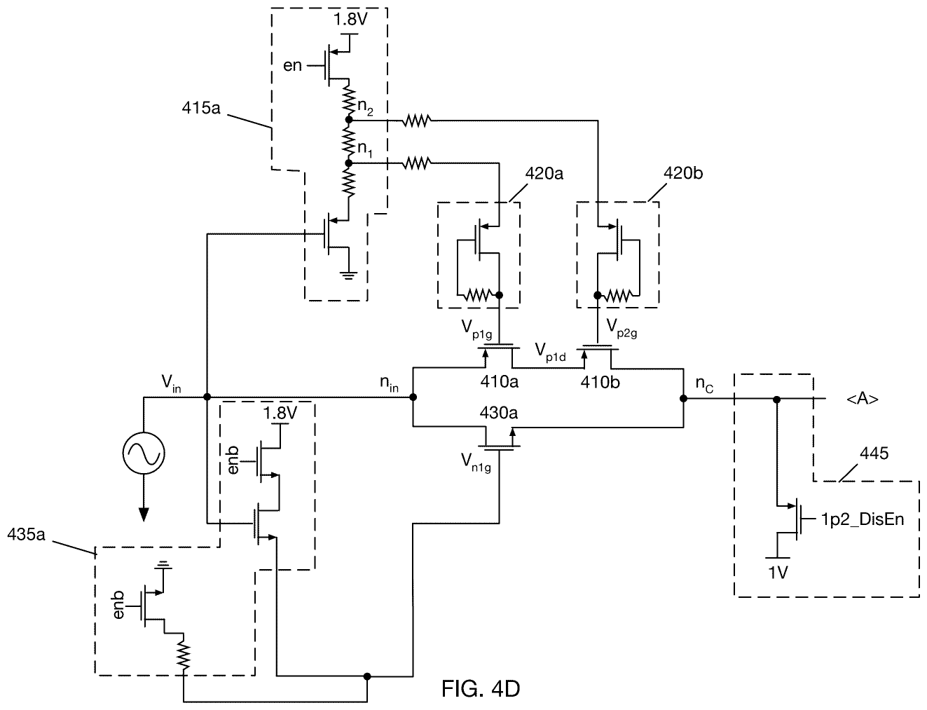

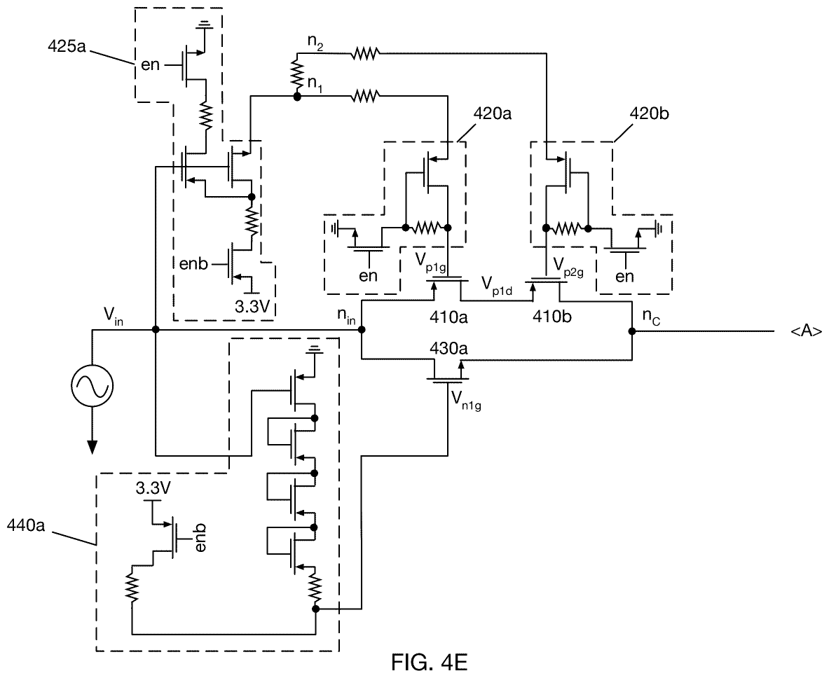

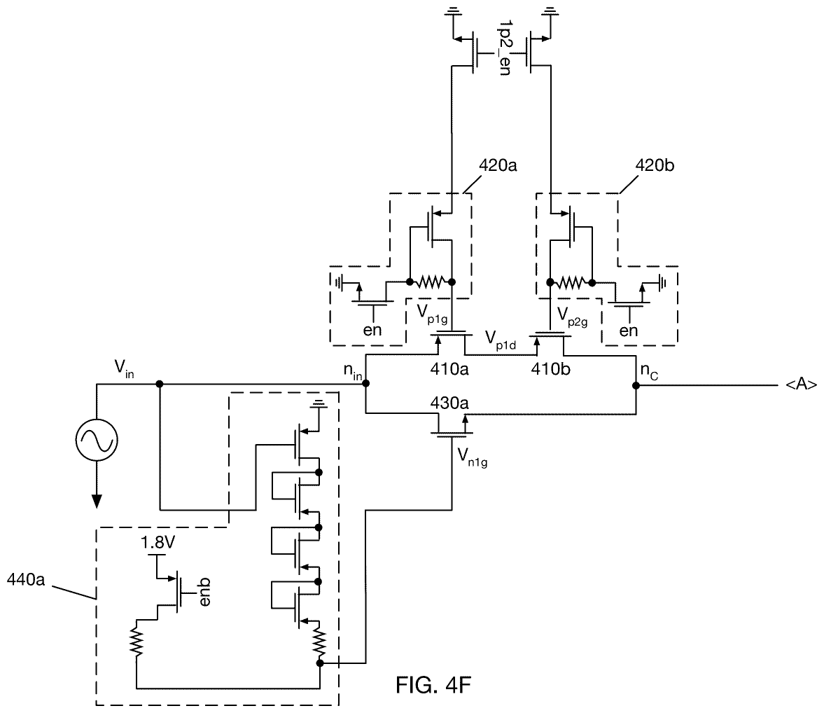

A more detailed schematic of system 100 is shown in FIG. 2. Four feedthrough switches 140a-140d are shown in FIG. 2, grouped into two pairs—this is explained in more detail in connection with FIGS. 4A and 4B later in this disclosure.

Each feedthrough switch is part of either feedthrough path 200a or feedthrough path 200b. The feedthrough paths 200a, 200b each provide a signal path that bypasses Sideband Use (SBU) cores 205a, 205b, i.e. when feedthrough switches 140a-140d are enabled (closed, i.e. conducting) they allow signals to be exchanged between first device 105 and second device 125 via feedthrough paths 200a, 200b so that SBU cores 205a, 205b do not receive these signals.

By way of providing context that is helpful to understand the invention, a scenario in which feedthrough paths 200a, 200b may be used is in the case of a USB 4.x or USB 4 v2 (hereafter ‘USB 4’) signalling link. USB 4 supports tunnelling of other protocols including USB 3.x and DisplayPort. USB 3.x does not define any sideband channel or signalling but DisplayPort and USB 4 do, hence there is a need to provide sideband use pins (SBU pins) for these two latter protocols in the pinout of a connector supporting USB 4. For example, in the case of a USB-C connector, two sideband pins SBU1 and SBU2 are provided. These are used for sideband signalling by DisplayPort and USB 4, but are unused by USB 3.x. SBU cores 205a, 205b are included in the sideband signalling path in the case of DisplayPort and USB 4 because the sideband signalling protocol is defined in the relevant standard and thus is intelligible to SBU cores 205a, 205b.

Given this information, it at first appears that feedthrough paths 200a, 200b are unnecessary because no sideband signals are sent when in USB 3.x mode. However, it is desirable to have the option to extend the USB 3.x protocol beyond that defined in the USB 3.x specification, i.e. to use the sideband pins SBU1 and SBU2 in a proprietary fashion when in USB. 3.x mode. As this signalling is a proprietary extension of the USB 3.x protocol, the details of the signalling will vary depending on the manufacturer of devices 105 and 125. This means that it is at least not practical for SBU cores 205a, 205b to support these proprietary protocols, meaning that a mechanism for bypassing SBU cores 205a, 205b is needed when operating in USB 3.x mode. Hence, in this exemplary scenario, the need for feedthrough paths 200a, 200b is apparent.

In USB 3.x mode feedthrough switches 140a-140d are enabled (i.e. they are closed and hence conductive) such that the feedthrough path is enabled. This means that signals sent via sideband pins SBU1 and SBU2 bypass SBU cores 205a, 205b of retimer 110. In DisplayPort and USB 4 modes, feedthrough switches 140a-140d are disabled (i.e. they are open and hence non-conductive) so that the feedthrough path is disabled. This means that signals sent via sideband pins SBU1 and SBU2 are received by SBU cores 205a, 205b of retimer 110. In this disabled mode, it is desirable for feedthrough switches 140a, 140b to have a relatively low leakage current so that signals do not leak into the feedthrough path to any appreciable degree.

This scenario is provided purely to illustrate an environment in which embodiments may operate and is not limiting on this disclosure, as the embodiments described herein have utility in any scenario in which it is desirable to provide a switch that has relatively low leakage current when off and that is also capable of preventing respective rating voltages of its constituent transistors from being exceeded during normal operation. Embodiments also find utility in critical situations in which supply voltage is limited, particularly where a supply voltage maximum value is lower than an input voltage maximum value. In such a scenario sideband pins SBU1, SBU2 are replaced with any kind of first input pin and second input pin, respectively, and SBU cores 205a, 205b are respectively replaced with a first circuit and second circuit of any kind.

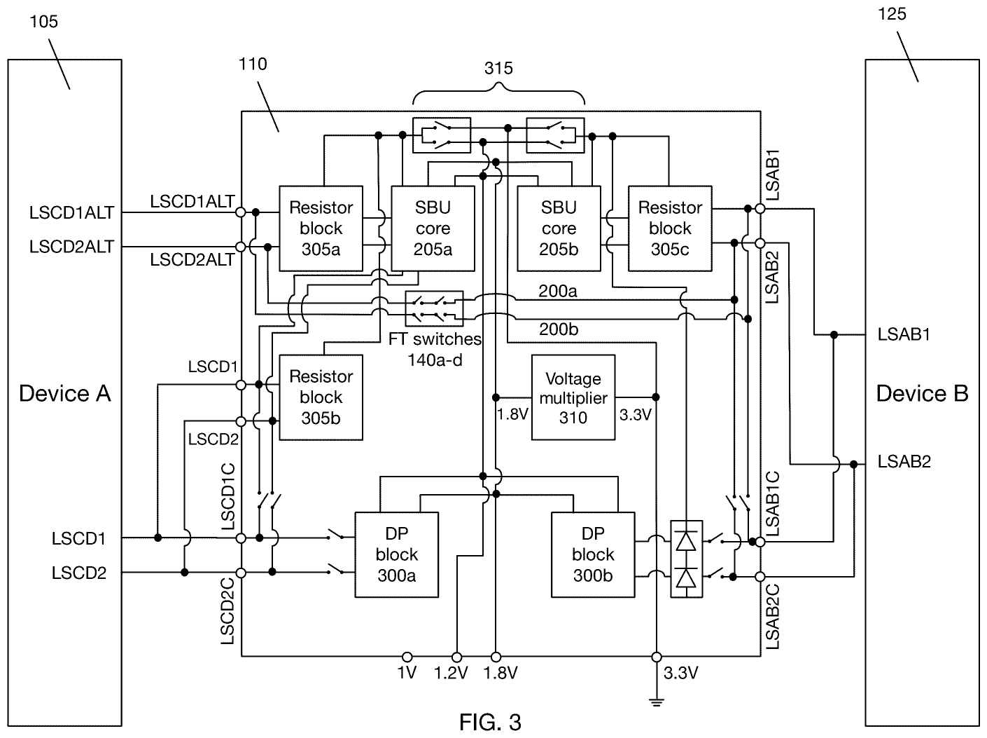

FIG. 3 is a schematic diagram of system 100 providing further detail relative to FIG. 2. First device 105 includes four pins, in two pairs: LSCD1 and LSCD2 as a first pair, and LSCD1ALT and LSCD2ALT as a second pair. ‘ALT’ specifies that the pins are alternate pins, meaning that in use either the LSCD1 and LSCD2 are in use, or the LSCD1ALT and LSCD2ALT pins are in use. This pin configuration is not essential and other configurations are possible, e.g. omission of the LSCD1ALT and LSCD2ALT pins, or shorting the LSCD1ALT and LSCD2ALT pins with the LSCD1 and LSCD2 pins, respectively, to allow the ‘ALT’ pins to be used for DisplayPort (DP) signalling (see FIG. 3).

In the illustrated embodiment, the LSCD1 and LSCD2 pins are used in a DisplayPort mode. The processing that retimer 110 is required to perform in DisplayPort mode is implemented by DisplayPort (DP) blocks 300a and 300b. As can be seen, DP block 300a is coupled to LSCD1 and LSCD2 pins, and DP block 300b is coupled to the LSAB1 and LSAB2 pins of second device 125. Feedthrough (FT) switches 140a-140d are not part of the DisplayPort signal path because there is no requirement for a bypass in DisplayPort mode. It should be noted that this is not essential as the DisplayPort signal path can include FT switches 140a, 140b set in disabled mode.

The LSCD1ALT and LSCD2ALT pins are used in USB 3.x and USB 4 modes. Two alternate signal paths are available-one via SBU cores 205a, 205b, which is used in USB 4 mode with feedthrough switches 140a-140d disabled, and the other via the feedthrough paths 200a, 200b, which is used in USB 3.x mode with feedthrough switches 140a-140d enabled. This results in signals that are transmitted or received via the LSCD1ALT and LSCD2ALT pins travelling via feedthrough paths 200a, 200b in USB 3.x mode and travelling via SBU cores 205a, 205b in USB 4 mode.

Retimer 110 also includes three resistor blocks 305a, 305b and 305c. Resistor block 305a is coupled between the LSCD1ALT and LSCD2ALT pins and SBU core 205a. Resistor block 305b is coupled between the LSCD1 and LSCD2 pins and SBU core 205a. Resistor block 305c is coupled between the LSAB1 and LSAB2 pins and SBU core 205b. Each resistor block comprises a set of resistors of varying resistance and switching circuitry that allows different ones of the resistors to be switched in and out of active use. The configuration of each resistor block varies according to the protocol currently in use (DisplayPort, USB 3.x, USB 4) and ensures that certain aspects of the relevant protocol are met. The construction and configuration of the resistor blocks is thus determined by reference to the relevant standard.

Retimer 110 has four possible supply voltages to select from: 1V, 1.2V, 1.8V and 3.3V. The 1V, 1.2V and 1.8V supply voltages are not generated by retimer 110 but are instead provided by another component in system 100, e.g. first device 105. The 3.3V supply is generated by a voltage multiplier 310 that is part of retimer 110. Voltage multiplier 310 receives 1.8V at an input and outputs 3.3V. Voltage multiplier 310 operates as is known in the art and thus further information is not provided here. The supply voltage levels are set by the protocols that first device 105 and second device 125 use to communicate, e.g. DisplayPort, USB 3.x, USB 4. Thus, different supply voltages may be available if different protocols are used. A voltage supply switching circuit 315 is included in retimer 110 and is configured to provide a selected one of the available supply voltages to various components of retimer 110, e.g. the SBU cores and resistor blocks.

Note that the sideband voltage signal is not constrained by the available supply voltages and thus can exceed the available supply voltages at least some of the time. One exemplary sideband voltage signal is a two-level digital signal having a LOW level of 0V and a HIGH level of 3.73V. Another exemplary sideband voltage signal is a two-level digital signal having a LOW level of 0V and a HIGH level of 1.2V. These voltage levels should not be construed as limiting on this disclosure as the principles set out herein can be applied to any sideband voltage signal levels.

It should be appreciated that the configuration of system 100 shown in FIG. 3 is just one way in which system 100 can be configured. Many other configurations are possible, e.g. pins LSCD1ALT and LSCD2ALT can be omitted so that pins LSCD1 and LSCD2 are used for all sideband signalling by shorting the LSCD and LSCDALT pins externally as discussed above.

FIGS. 4A and 4B together provide a detailed schematic of a feedthrough switch according to an embodiment. In these figures, feedthrough switches 140a and 140b are illustrated but it should be understood that feedthrough switches 140c and 140d are of the same construction.

FIG. 4A shows feedthrough switch 140a and FIG. 4B shows feedthrough switch 140b. The connection between these two feedthrough switches is marked as <A> on both figures such that these figures should be interpreted as one drawing joined at the point marked <A> on both figures.

It should be noted that FIG. 4B is largely identical to FIG. 4A, with the layout mirrored. The following description of components of FIG. 4A thus applies equally to the corresponding components of FIG. 4B, unless otherwise stated. To assist in the understanding of these figures, like elements have been given the same number in both figures, with a unique letter suffix to allow each component to be identified uniquely.

The feedthrough switch is described in the context of two operational modes-a 3.3V operational mode in which the sideband voltage signal Vᵢₙ is a digital voltage that has a LOW level of 0V and a HIGH level of 3.73V, and a 1.2V operational mode in which the sideband voltage signal Vᵢₙ is a digital voltage that has a LOW level of 0V and a HIGH level of 1.2V. The 3.3V mode corresponds to a USB standard voltage and the 1.2V mode is a voltage that is increasingly used in smaller process technologies (e.g. 12 nm process and smaller). Within each operational mode the feedthrough switch can be either enabled or disabled, resulting in a total of four states for the feedthrough switch. In order to assist in the understanding of the invention, FIGS. 4C to 4F show only those components of feedthrough switch 140a that are active in a given mode. The modes are as follows:
FIG. 4C: 3.3V blocking mode, feedthrough switch 140a disabled.
FIG. 4D: 1.2V blocking mode, feedthrough switch 140a disabled.
FIG. 4E: 3.3V passthrough mode, feedthrough switch 140a enabled.
FIG. 4F: 1.2V passthrough mode, feedthrough switch 140a enabled.

In FIGS. 4A to 4F, dashed lines have been used to group together certain components that co-operate in operation to provide a particular function. This is to aid in the understanding of embodiments and should not be interpreted as limiting a particular set of components to only those shown.

Various PMOS and NMOS devices are shown in FIGS. 4A-4F having either ‘en’ or ‘enb’ provided to their respective gates. ‘en’ and ‘enb’ are control voltages used to selectively enable or disable parts of feedthrough switch 140a or feedthrough switch 140b depending on the current operational mode of retimer 110. Specifically, en is set to HIGH and enb is set to LOW to activate a passthrough mode in which feedthrough switches 140a, 140b are enabled to allow the sideband voltage signal Vᵢₙ to propagate via the feedthrough path 200a. Conversely, en is set to LOW and enb is set to HIGH to activate a blocking mode in which feedthrough switches 140a, 140b are disabled to prevent the sideband voltage signal Vᵢₙ from propagating via the feedthrough path 200a. References to the passthrough mode and blocking mode below thus indicate the associated settings for the PMOS and NMOS devices.

FIGS. 4A and 4B respectively show two feedthrough switches 140a, 140b coupled in a feedthrough path 200a between a sideband use (SBU) input pin 400 and a SBU output pin 405. The feedthrough switches are configured, in the blocking mode, to prevent sideband voltage signal Vᵢₙ from being transmitted between the SBU input pin 400 and the SBU output pin 405 via the feedthrough path 200a. FIGS. 4C to 4F show only those components of feedthrough switch 140a that actively participate in a given mode, with the mode corresponding to each figure as explained above.

Feedthrough switch 140a comprises a cascode circuit comprising two PMOS devices 410a, 410b connected in series between an input node nᵢₙ and a center node n_{c}. The voltage at the drain of the first PMOS 410a, i.e. the voltage at the node between the two PMOS devices, is labelled V_{pld}. The input node nᵢₙ is coupled to a respective one of the SBU input pin 400 (FIG. 4A) and the SBU output pin 405 (FIG. 4B) and configured to receive the sideband voltage signal Vᵢₙ at a source of a first PMOS device 410a of the two PMOS devices.

A voltage source 400 is shown in FIG. 4A to represent the source of the sideband voltage signal Vᵢₙ. Voltage source 400 represents a coupling to a sideband voltage signal output of the first device 105 or second device 125 (see FIGS. 2 and 3). In this embodiment there are two operational modes-a 3.3V operational mode in which the sideband voltage signal Vᵢₙ is a digital voltage that has a LOW level of 0V and a HIGH level of 3.73V, and a 1.2V operational mode in which the sideband voltage signal Vᵢₙ is a digital voltage that has a LOW level of 0V and a HIGH level of 1.2V. Vᵢₙ approximates a square wave with respect to time in both modes. These values are not limiting on the scope of this disclosure as the principles disclosed herein can also be applied with a sideband voltage signal having different characteristics.

In one embodiment each PMOS device 410a, 410b is a FET, specifically a FinFET. The dimensions of each PMOS FinFET device can be: width=105 μm, L=135 nm. These device dimensions provide a low on resistance (Ron) for feedthrough switch, e.g. Ron is approximately 15 ohms or less across the whole voltage range of Vᵢₙ, i.e. from minimum Vᵢₙ to maximum Vᵢₙ. Here, Ron is the combined resistance of feedthrough switches 140a and 140b when in the passthrough mode. A low Ron is desirable since, in passthrough mode, the objective is for feedthrough switches 140a and 140b to allow the sideband voltage signal Vᵢₙ to traverse the feedthrough path 200a with minimal losses. It will be appreciated that this disclosure is not limited to the dimensions given above, as FETs with other dimensions can be used instead depending on the specifics of the implementation such as required Ron value.

The cascode arrangement is used to reduce the leakage current across the feedthrough switch 140a when operating in the blocking mode. The cascode arrangement has been found to limit leakage current to less than 400 nA at Vᵢₙ=0V to approximately 5.3 μA at Vᵢₙ=3.73V, for the FinFET devices described in the paragraph directly above. These leakage current levels are low enough for feedthrough switch 140a to be considered highly effective at blocking current when in the blocking mode.

The cascode circuit also comprises a cascode PMOS biasing circuit comprising a PMOS blocking voltage follower circuit 415a (FIGS. 4C & 4D) coupled to a supply voltage Vₛ and to the input node nᵢₙ. The PMOS blocking voltage follower circuit 415a is configured to, in the blocking mode, provide first and second level-shifted bias voltages V_{p1g}, V_{p2g} to gate inputs of the two PMOS devices 410a, 410b, the level-shifted bias voltages V_{p1g}, V_{p2g} tracking the sideband voltage signal Vᵢₙ according to a voltage offset to maintain the two PMOS devices 410a, 410b in a non-conductive state while the sideband voltage signal Vᵢₙ is below the supply voltage Vₛ. The tracking of the sideband voltage signal Vᵢₙ ensures that the respective source to gate voltages of PMOS device 410a and PMOS device 410b do not exceed the rated voltages of those PMOS devices.

The PMOS blocking voltage follower circuit 415a can comprise a voltage divider coupled to the supply voltage Vₛ and having first and second nodes n₁, n₂, wherein the first and second level-shifted bias voltages V_{p1g}, V_{p2g} are provided from the first and second nodes n₁, n₂, respectively. A resistor can be coupled between node n₁ and the gate of PMOS device 410a so that, in enabled mode, the gate voltage of PMOS device 410a can be set to the desired level by selection of the resistance of this resistor. In disabled mode, there is no DC current flowing through this resistor and so it is not affecting the overall circuit in any meaningful way. Similarly, another resistor can be coupled between node n₂ and the gate of PMOS device 410b to enable the gate voltage of PMOS device 410b to be set to the desired level when in enabled mode.

PMOS blocking voltage follower circuit 415a can comprise a first PMOS device having a gate coupled to the SBU input pin 400 or SBU output pin 405 to receive sideband voltage signal Vᵢₙ. The first PMOS device is coupled between ground and a resistor string comprising three resistors coupled in series. The other end of the resistor string is coupled to a second PMOS device that receives enable signal en at its gate. The second PMOS device is also coupled to supply voltage Vs. This arrangement creates a voltage divider that provides a voltage at each node of the resistor string such that each node n₁, n₂ tracks the sideband voltage signal Vᵢₙ.

As shown in FIGS. 4A and 4C, the resistor string has two nodes n₁ and n₂. Node n₁ is coupled to the gate of PMOS device 410a and node n₂ is coupled to the gate of PMOS device 410b to respectively generate the first and second level-shifted bias voltages V_{p1g}, V_{p2g} at the gates of the first and second PMOS devices 410a, 410b. The voltage Vₙ₁ at node n₁ is lower than the voltage Vₙ₂ at node n₂ at Vᵢₙ=0V, meaning that V_{p1g}<V_{p2g} at Vᵢₙ=0V. That is, a minimum voltage of the first level-shifted bias voltage is lower than a minimum voltage of the second level-shifted bias voltage.

In the 3.3V operational mode of retimer 110 where the feedthrough switch 140a is disabled (FIG. 4C) and the supply voltage Vₛ=3.3V, the voltage V_{p1g} at the gate of PMOS device 410a ranges from approximately 1.5V to 3.3V as Vᵢₙ ranges from 0V to 3.73V and the voltage V_{p2g} at the gate of PMOS device 410b ranges from approximately 2V to 3.3V as Vᵢₙ ranges from 0V to 3.73V. The voltages at nodes n₁ and n₂ are proportional to the voltages at the gates of the PMOS devices 410a, 410b. The values above are not limiting on the scope of this disclosure as other voltage ranges are possible.

In a 1.2V operational mode of retimer 110 where the feedthrough switch 140a is disabled (FIG. 4D) and the supply voltage Vₛ=1.8V, the voltage V_{p1g} at the gate of PMOS device 410a ranges from approximately 0.8V to 1.58V as Vᵢₙ ranges from 0V to 1.2V and the voltage V_{p2g} at the gate of PMOS device 410b ranges from approximately 1.2V to 1.66V as Vᵢₙ ranges from 0V to 1.2V. The voltages at nodes n₁ and n₂ are at approximately the same voltage as the respective gates of the PMOS devices 410a, 410b. These values are not limiting on the scope of this disclosure as other voltage ranges are possible.

The cascode PMOS biasing circuit also comprises an overstress prevention voltage supply 445 that supplies an overstress prevention voltage Vₒₛₚ. The overstress prevention voltage supply 445 is configured to, in the blocking mode, bias the center node ne with a fixed voltage. Here, fixed indicates that Vₒₛₚ does not vary over time. The overstress prevention voltage supply can be configured to set the fixed voltage Vₒₛₚ to a value that is between a maximum voltage of the sideband voltage signal and a minimum voltage of the sideband voltage signal. More specifically, the fixed voltage Vₒₛₚ can be set to a value that is less than or equal to the difference between a maximum rated drain to source voltage of NMOS device 430a and a minimum voltage of the sideband voltage signal and greater than or equal to the difference between a maximum voltage of the sideband voltage signal and the maximum rated drain to source voltage of NMOS device 410a. This will ensure that the maximum rated drain to source voltage of NMOS device 410a is not exceeded for all values of the sideband voltage signal, preventing overstress of NMOS device 430a.

In the illustrated embodiment, as there are two PMOS devices 410a, 410b, the voltage stress is shared between these two PMOS devices and hence ensuring that the drain to source voltage of NMOS device 430a does not exceed its maximum rated voltage will automatically ensure that both PMOS devices 410a, 410b are also not overstressed. Further consideration might be necessary in the case of only a single PMOS device being present in the circuit, e.g. just PMOS device 410a.

In the illustrated embodiment the maximum rated drain to source voltage of NMOS device 410a is 2.1V. The maximum rated drain to source voltage of each of PMOS devices 410a, 430a is also 2.1V in this embodiment, but these values do not have to be the same as each other. In the 3.3V operational mode, the minimum voltage of the sideband voltage signal is 0V and the maximum voltage of the sideband voltage signal is 3.73V. Thus Vₒₛₚ is set to a value that is less than or equal to 2.1V−0V=2.1V and also greater than or equal to 3.73V−2.1V=1.63V, i.e. 1.63V≤Vₒₛₚ≤2.1V. Given that a 1.8V supply is available in retimer 110 (FIG. 3), Vₒₛₚ=1.8V is particularly advantageous given that it satisfies the inequality above and does not require any additional circuitry to generate another voltage from the supply voltages available. However, this disclosure is not limited to Vₒₛₚ=1.8V as any value for Vₒₛₚ that meets the requirements above can be used.

In 1.2V operation mode, applying the principles established above the inequality that Vₒₛₚ should satisfy to prevent overstress of NMOS device 430a is as follows: −0.9V≤Vₒₛₚ≤1.2V. A value of 1V is used in the illustrated embodiment, but this is not limiting as any value that satisfies the inequality above can be used. It should also be understood that the bounds of this inequality are implementation-specific, so in a case where Vᵢₙ has a different maximum and/or minimum value, and/or the maximum rated drain to source voltage of the NMOS device is different, the bounds of this inequality will change accordingly. The general form of the inequality is:

$${V}_{in , max} - {V}_{rated} \leq {V}_{osp} \leq {V}_{rated} - {V}_{in , min}$$

where V_{in,max} is the maximum sideband signal voltage, V_{rated} is the maximum rated drain to source voltage of NMOS device 430a and V_{in,min} is the minimum sideband signal voltage.

Advantageously, the biasing provided by the overstress prevention voltage supply ensures that, in both operational modes, PMOS devices 410a, 410b and NMOS device 430a at all times experience a drain to source voltage that is within their respective specifications and thus are not overstressed.

FIG. 4B does not show a corresponding overstress prevention voltage supply because overstress prevention voltage supply 445 of FIG. 4A is sufficient to provide the overstress prevention voltage Vₒₛₚ to both portions of the overall circuit. Control signals 3p3_DisEn and 1p2_DisEn are used to select between Vₒₛₚ=1.8V and Vₒₛₚ=1V modes respectively corresponding to the 3.3V and 1.2V modes of operation, with it being understood that the control signals are set such that one of the corresponding PMOS devices is ON whilst the other is OFF.

The cascode PMOS biasing circuit optionally further comprise a first bias current blocking circuit 420a configured to inhibit discharge of the first bias voltage V_{p1g} on the gate input of the first PMOS device 410a when the sideband voltage signal Vᵢₙ exceeds the supply voltage Vₛ. The first bias blocking circuit 420a can be implemented using a diode-connected transistor as is shown in FIG. 4A, where the gate and drain of a PMOS transistor are coupled together to create a diode-like mode of operation. Alternatively, a diode can be used to implement the first bias blocking circuit 420a. Other circuit components that inhibit the flow of current in one direction can also be used to implement first bias blocking circuit 420a. More specifically, in the blocking mode in which the feedthrough switch is disabled (FIGS. 4C and 4D), the first bias current blocking circuit 420a behaves like a diode. However, in the passthrough mode in which the feedthrough switch is enabled (FIGS. 4E and 4F), the first bias current blocking circuit 420a behaves like a switch and allows current to flow through the resistor coupled to the drain of the diode-connected transistor. This creates a voltage divider and allows the voltage at the gate of PMOS 410a to be controlled accordingly.

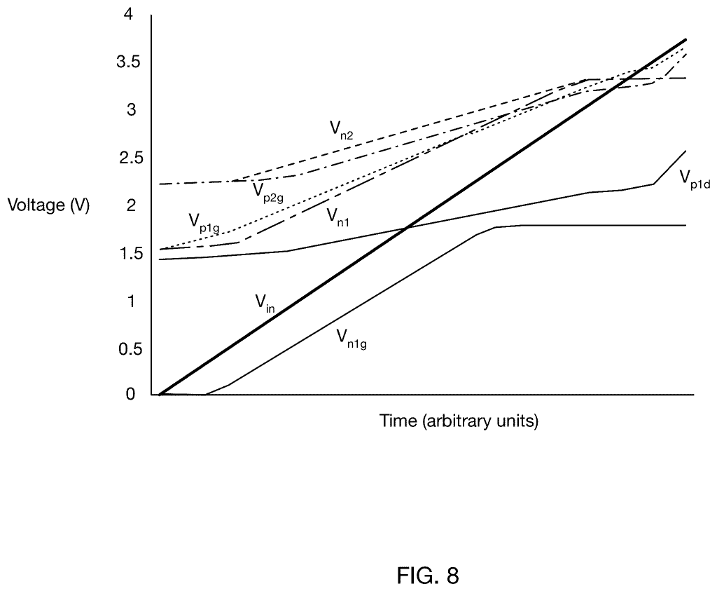

In a particular embodiment, Vᵢₙ has a maximum voltage of 3.73V and Vₛ is 3.3V in a 3.3V operating mode of retimer 110 (FIG. 4C). In this embodiment, when feedthrough switches 140a are in the blocking mode, first bias current blocking circuit 420a inhibits discharge of the first bias voltage V_{p1g} when Vᵢₙ is greater than the 3.3V supply voltage. This causes the first bias voltage V_{p1g} to increase above the supply voltage of 3.3.V and to approximately track the input voltage Vᵢₙ. This can be seen in FIG. 8, particularly the upper right corner of the figure which shows the first bias voltage V_{p1g} approximately tracking Vᵢₙ for Vᵢₙ>3.3V.

Without being bound by theory, it is believed that this voltage tracking effect arises from a capacitive coupling between the source and gate of PMOS device 410a that occurs because first bias current blocking circuit 420a prevents the gate voltage from dropping in the operational regime in which Vᵢₙ>Vₛ.

First bias current blocking circuit 420a can also include a path to ground via an NMOS device acting essentially as a switch coupled in series with a resistor. The NMOS device is off when in the blocking mode, to prevent discharge of the gate of PMOS 410a via the path to ground. In the passthrough mode (FIGS. 4E and 4F), the NMOS device is on and acts as a voltage divider such that the voltage at the gate of PMOS device 410a, V_{p1g}, varies from 0V to 1.9V as the input voltage varies from 0 to 3.73V. Specifically, the voltage V_{p1g} is given by:

$${V}_{p 1 g} = [ {V}_{in} - {V}_{gs} ] \frac{{R}_{1}}{{R}_{1} + {R}_{2}}$$

Here, V_{gs} is the gate to source voltage of the NMOS device that is part of NMOS passthrough voltage follower 425a, R₁ is the resistance of the resistor located between node n₁ and the NMOS device, and R₂ is the resistance of the resistor located between the gate and drain of the NMOS device. Selection of R₁ and R₂, as well as adjusting the properties of the NMOS device that is part of NMOS passthrough voltage follower 425a, thus enables the gate voltage of PMOS 410a to be controlled across the range of values of the input voltage. A similar analysis can be made for PMOS device 410b.

The cascode PMOS biasing circuit optionally further comprises a second bias current blocking circuit 420b configured to, in the blocking mode, inhibit discharge of the second bias voltage V_{p2g} on the gate input of the second PMOS device 410b when the sideband voltage signal Vᵢₙ exceeds the supply voltage Vₛ. The second bias current blocking circuit 420b functions in the same manner as the first bias current blocking circuit 420a and can be constructed in the same manner also.

The second bias current blocking circuit 420b is not necessary from a circuit operation perspective as it is sufficient that first PMOS device 410a tracks Vᵢₙ when Vᵢₙ>Vₛ for both first and second PMOS devices 410a, 410b to remain in a non-conductive state across the expected voltage range of the sideband voltage signal, i.e. for all voltages between 0V and 3.73V in this embodiment. However, it may be beneficial to include the second bias current blocking circuit 420b at least for circuit symmetry reasons and/or to further reduce any leakage current, e.g., to reduce the leakage current such that it is at most of the order of hundreds of nanoamps.

Referring specifically here to FIG. 4E, feedthrough switch 410a can optionally also include a PMOS passthrough voltage follower 425a coupled to the supply voltage Vₛ and to the input node nᵢₙ. The PMOS passthrough voltage follower 425a is configured to, in the passthrough mode in which the sideband voltage signal Vᵢₙ is transmitted via the sideband channel 200a, provide third and fourth level-shifted bias voltages to the gate inputs of the two PMOS devices 410a, 410b, the level-shifted bias voltages tracking the sideband voltage signal according to a voltage offset to maintain the two PMOS devices 410a, 410b in a conductive state for a first portion of a sideband voltage signal range.

The PMOS passthrough voltage follower 425a can comprise a PMOS device coupled between ground and the supply voltage Vₛ, with the gate of this PMOS device coupled to either the SBU input pin or SBU output pin to receive the sideband voltage signal Vᵢₙ. A NMOS device is coupled via its drain to a node between the source of the PMOS device and the supply voltage, with the gate of this NMOS device also being coupled to either the SBU input pin or SBU output pin to receive the sideband voltage signal Vᵢₙ. The NMOS device is also coupled to node n₁ of PMOS blocking voltage follower circuit 415a.

The PMOS device functions to provide a lower local supply voltage to the NMOS device such that, when the input voltage is at lower values, the stress on the NMOS device is reduced. The PMOS device can thus be omitted in cases where the input voltage and/or rating of the NMOS device is such that this overstress protection is not required.

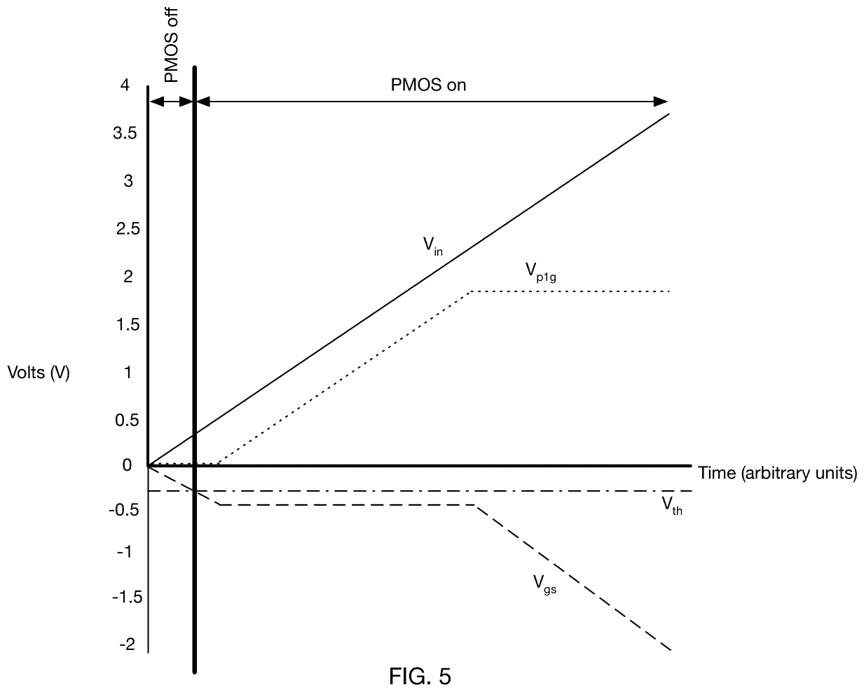

The NMOS device functions to follow the input voltage so that PMOS passthrough voltage follower 425a maintains the two PMOS devices 410a, 410b in a conductive state for a first portion of the sideband voltage signal range. The first portion can be an upper portion of the sideband voltage signal range. The upper portion of the sideband voltage signal range can be a subrange spanning from an intermediate voltage level that is greater than a minimum sideband voltage signal level to a maximum sideband voltage signal level. The intermediate voltage level can be the threshold voltage of PMOS device 410a. Numerically, this subrange can be expressed as [Vₜₕ, Vₘₐₓ], where Vₘₐₓ is a maximum voltage of the sideband voltage signal and Vₜₕ is the threshold voltage of PMOS device 410a. PMOS devices 410a, 410b are ON in this subrange and OFF for all voltage levels of the sideband voltage signal that are below the minimum voltage Vₜₕ of this subrange. This is shown graphically in FIG. 5.

Thus, for example, in the case where the sideband voltage signal ranges from 0V to 3.73V and the threshold voltage of PMOS device 410a is 0.335V, the first portion of the sideband voltage signal can be the subrange 0.335V to 3.73V. These values are purely exemplary and are not limiting on the scope of this disclosure.

The behaviour of PMOS device 410b is similar to that of PMOS device 410a, and reference is made in this connection to FIG. 8.

Feedthrough switch 140a can also include a NMOS device 430a coupled in parallel with the cascode circuit. The NMOS device 430a can be a FET, e.g. a FinFET.

Feedthrough switch 140a can further include a NMOS blocking voltage follower circuit 435a (FIGS. 4C & 4D) coupled to the supply voltage Vₛ and to the input node nᵢₙ. The NMOS blocking voltage follower circuit 435a is configured, in the blocking mode, to provide a first NMOS level-shifted bias voltage to a gate input of the NMOS device 430a, the first NMOS level-shifted bias voltage tracking the sideband voltage signal Vᵢₙ according to a voltage offset to maintain the NMOS device 430a in a non-conductive state.

The NMOS blocking voltage follower circuit 435a can comprise an NMOS device coupled between the supply voltage Vₛ and ground. The gate of the NMOS device is coupled to either the SBU input pin or SBU output pin to receive the sideband voltage signal Vᵢₙ. The gate of NMOS device 430a is coupled to a node that is between the NMOS device of the NMOS blocking voltage follower circuit and ground.

The NMOS blocking voltage follower circuit 435a maintains the NMOS device 430a in an OFF state for all expected voltage levels of the sideband voltage signal Vᵢₙ. In the case where retimer 110 operates in a 3.3V mode and a 1.2V mode, Vᵢₙ is expected to range from 0V to 3.73V in the 3.3V mode and 0V to 1.2V in the 1.2V mode. Thus, in this case NMOS blocking voltage follower circuit 435a maintains the NMOS device 430a in an OFF state for the entire range 0V to 3.73V.

Feedthrough switch 140a optionally further includes a NMOS passthrough voltage follower circuit 440a (FIGS. 4E & 4F) that is coupled to the supply voltage Vₛ and to the input node nᵢₙ. The NMOS passthrough voltage follower circuit 440a is configured to, in the passthrough mode in which the sideband voltage signal Vᵢₙ is transmitted via the sideband channel 200a, provide a second NMOS level-shifted bias voltage to the gate input of the NMOS device 430a, the second NMOS level-shifted bias voltage tracking the sideband voltage signal according to a voltage offset to maintain the NMOS device in a conductive state for a second portion of the sideband voltage signal range.

The NMOS passthrough voltage follower 440a can comprise a PMOS device coupled between ground and the supply voltage Vₛ, with the gate of this PMOS device coupled to either the SBU input pin or SBU output pin to receive the sideband voltage signal Vᵢₙ. One or more diode-connected transistors can be coupled between the PMOS device and the supply voltage Vₛ.

The gate of NMOS device 430a is connected to a node that is located between the one or more diode-connected transistors and the supply voltage Vₛ. In the illustrated embodiment three diode-connected transistors are present, but this value is not limiting on the scope of this disclosure as any number of diode-connected transistors (or circuit component with equivalent functionality, e.g. diodes) can be present. It is also possible to entirely omit the diode-connected transistors.

The NMOS passthrough voltage follower 440a maintains NMOS device 430a in a conductive state for a second portion of the sideband voltage signal range. The second portion can be a lower portion of the sideband voltage signal range. The lower portion of the sideband voltage signal range can be a subrange spanning from a minimum sideband voltage signal level to an intermediate voltage level that is less than a maximum sideband voltage signal level.

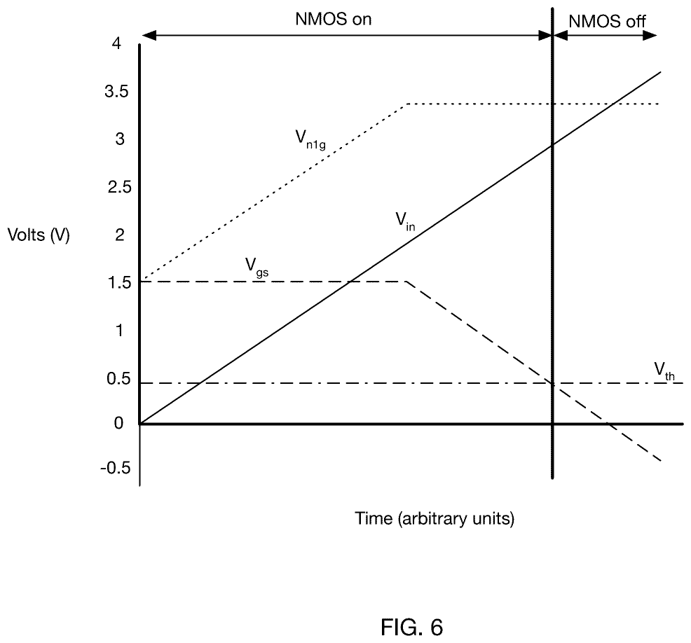

The intermediate voltage level can be equal to the difference between the supply voltage and a threshold voltage of the NMOS device 430a. Numerically, this subrange can be expressed as [Vₘᵢₙ, Vₛ−Vₜₕ], where Vₘᵢₙ is a minimum voltage of the sideband voltage signal, Vₛ is the supply voltage and Vₜₕ is the threshold voltage of NMOS device 430a. NMOS device 430a is ON in this subrange and OFF for all values of the sideband voltage signal that exceed the maximum voltage Vₛ−Vₜₕ of this subrange. This is shown graphically in FIG. 6.

Thus, for example, in the case where the sideband voltage signal ranges from 0V to 3.73V the supply voltage Vₛ is 3.3V and the threshold voltage of NMOS device 430a Vₜₕ is 0.489V, the second portion of the sideband voltage signal can be the subrange 0V to 2.811V. These values are purely exemplary and are not limiting on the scope of this disclosure.

Referring specifically to FIG. 4F, in the 1.2V operational mode the PMOS passthrough voltage follower 425a does not have any effect on the rest of the circuit and thus it is not strictly necessary in this operational mode. In place of the PMOS passthrough voltage follower 425a is a pair of connections to ground, each connected to a respective one of the gates of PMOS 410a and PMOS 410b. A pair of NMOS devices are respectively coupled between the gates of the PMOS devices and ground to act as switches to selectively enable the connection to ground in the 1.2V operational mode. These NMOS devices are operated by a control signal 1p2_en.

It can be seen from the above that the PMOS passthrough voltage follower 425a and NMOS passthrough voltage follower 440a can co-operate to keep feedthrough switch 140a open for the entire sideband voltage signal range. This is because the following are true: the first portion of the sideband voltage signal range partially overlaps the second portion of the sideband voltage signal range; the first portion of the sideband voltage signal range and the second portion of the sideband voltage signal range collectively span all of the sideband voltage signal range; and a minimum voltage of the first portion of the sideband voltage signal range is less than a maximum voltage of the second portion of the sideband voltage signal range.

For example, using the values given above for a 3.3V mode of operation, PMOS 410a is ON for Vᵢₙ=0.335V to 3.73V and NMOS 430a is ON for Vᵢₙ=0V to 2.811V. PMOS 410b is ON at least for all voltages that PMOS 410a is ON. Thus for all values of Vᵢₙ between the minimum sideband voltage signal of 0V and the maximum sideband voltage signal of 3.73V, PMOS 410a and PMOS 410b are ON and/or NMOS 430a is ON, so that a conductive path is present for the whole range of values for Vᵢₙ.

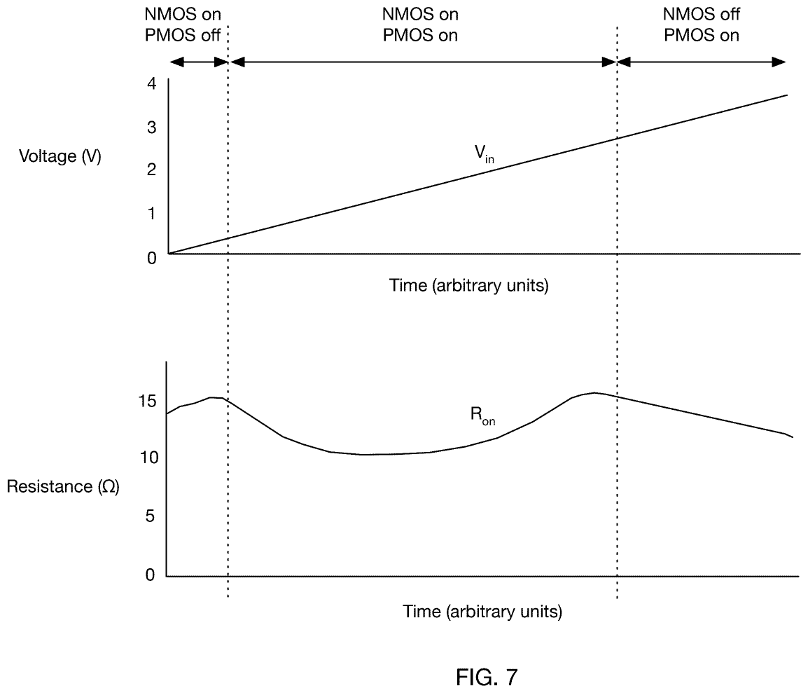

Generally speaking there are three regimes: a low sideband voltage signal regime where only NMOS 430a is ON, a middle sideband voltage signal regime where all of NMOS 430a, PMOS 410a and PMOS 410b are ON, and a high sideband voltage signal regime where only PMOS 410a and PMOS 410b are ON. These regimes are shown in FIG. 7 which shows Ron as a function of time as Vᵢₙ increases from its minimum to maximum value. As can be seen, Ron remains at approximately 15 ohms for the entire sideband voltage signal range, comfortably below a 17-ohm upper limit derived from a 40-ohm overall upper limit imposed by the USB 3.x specification. It is worth noting that the resistance curve shown in FIG. 7 is the resistance at the most extreme process-voltage-temperature (PVT) corner and so under many operating conditions encountered in practice Ron is expected to be lower than as shown in FIG. 7.

FIG. 8 shows the various voltages discussed above in connection with the 3.3V blocking mode as a function of time. As can be seen, the gate voltage V_{p1g} of the first PMOS device 410a tracks the sideband signal voltage Vᵢₙ across the full range, including the upper right corner of the figure where Vᵢₙ>Vₛ. This ensures that PMOS device 410a remains off for the full voltage range of the sideband voltage signal. The same is true for the gate voltage V_{p2g} of the second PMOS device 410b, as well as the gate voltages of the third and fourth PMOS devices V_{p3g} and V_{p4g} which approximately behave the same as V_{p1g} and V_{p2g}, respectively. Thus, current cannot flow via the feedthrough path in the blocking mode.

FIG. 8 shows a slow input ramp 4 us approx. and illustrates the capacitive coupling effect between the source and gate of PMOS device 410a depicted in the top right-hand section where the PMOS device 410a is not conducting. The magnitude of the capacitive coupling is determined by input edge rate, but will occur at all input frequencies.

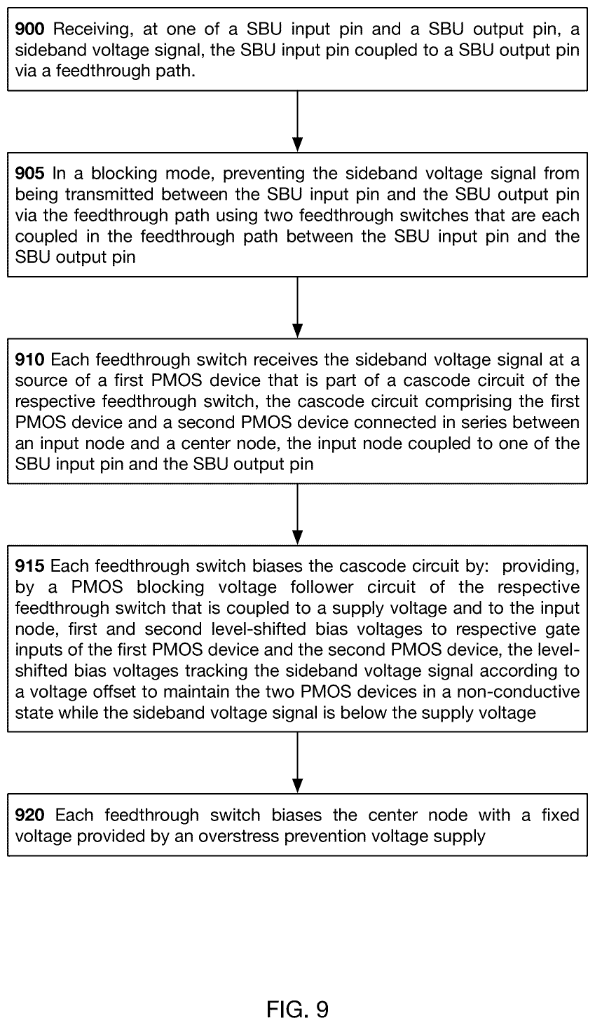

FIG. 9 shows a method according to an embodiment. Element 900 comprises receiving, at one of a SBU input pin and a SBU output pin, a sideband voltage signal, the SBU input pin coupled to a SBU output pin via a feedthrough path.

Element 905 comprises, in a blocking mode, preventing the sideband voltage signal from being transmitted between the SBU input pin and the SBU output pin via the feedthrough path using two feedthrough switches that are each coupled in the feedthrough path between the SBU input pin and the SBU output pin.

The blocking of element 905 is performed as shown in elements 910 to 920.

Specifically, in element 910, each feedthrough switch receives the sideband voltage signal at a source of a first PMOS device that is part of a cascode circuit of the respective feedthrough switch, the cascode circuit comprising the first PMOS device and a second PMOS device connected in series between an input node and a center node, the input node coupled to one of the SBU input pin and the SBU output pin.

In element 915, each feedthrough switch biases the cascode circuit by: providing, by a PMOS blocking voltage follower circuit of the respective feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage.

In element 920, each feedthrough switch biases the center node with a fixed voltage provided by an overstress prevention voltage supply.

It will be apparent to a person skilled in the art having the benefit of the present disclosure that various modifications, extensions, substitutions and the like to the subject matter described herein are possible. Such changes are also within the scope of this disclosure. It is also noted that, where method steps are described, these steps can be performed in any order unless expressly stated otherwise.

For example, while the majority of the disclosure focusses on a feedthrough path including two feedthrough switches, it is possible for the teaching provided herein to be applied to a feedthrough path that includes just one feedthrough switch. In this embodiment the feedthrough switch can comprise the components disclosed in FIG. 4A without FIG. 4B being present.

The following clauses set out further embodiments of this disclosure, in addition to the embodiments described above.

Clause 1: An apparatus, comprising: two feedthrough switches coupled in a feedthrough path between a sideband use (SBU) input pin and a SBU output pin and configured, in a blocking mode, to prevent a sideband voltage signal from being transmitted between the SBU input pin and the SBU output pin via the feedthrough path, each feedthrough switch comprising: a cascode circuit comprising two PMOS devices connected in series between an input node and a center node, the input node coupled to a respective one of the SBU input pin and the SBU output pin and configured to receive the sideband voltage signal at a source of a first PMOS device of the two PMOS devices; a cascode PMOS biasing circuit comprising: a PMOS blocking voltage follower circuit coupled to a supply voltage and to the input node and configured to, in the blocking mode, provide first and second level-shifted bias voltages to gate inputs of the two PMOS devices, the level-shifted bias voltages tracking the sideband voltage signal according to a voltage offset to maintain the two PMOS devices in a non-conductive state while the sideband voltage signal is below the supply voltage; and an overstress prevention voltage supply configured to, in the blocking mode, bias the center node with a fixed voltage.

Clause 2: An apparatus, comprising: a feedthrough switch coupled in a feedthrough path between a sideband use (SBU) input pin and a SBU output pin and configured, in a blocking mode, to prevent a sideband voltage signal from being transmitted between the SBU input pin and the SBU output pin via the feedthrough path, the feedthrough switch comprising: a cascode circuit comprising two PMOS devices connected in series between an input node and a center node, the input node coupled to a respective one of the SBU input pin and the SBU output pin and configured to receive the sideband voltage signal at a source of a first PMOS device of the two PMOS devices; a cascode PMOS biasing circuit comprising: a PMOS blocking voltage follower circuit coupled to a supply voltage and to the input node and configured to, in the blocking mode, provide first and second level-shifted bias voltages to gate inputs of the two PMOS devices, the level-shifted bias voltages tracking the sideband voltage signal according to a voltage offset to maintain the two PMOS devices in a non-conductive state while the sideband voltage signal is below the supply voltage; and an overstress prevention voltage supply configured to, in the blocking mode, bias the center node with a fixed voltage.

Clause 3: The apparatus of clause 1 or clause 2, wherein the cascode PMOS biasing circuit further comprises a first bias current blocking circuit configured to, in the blocking mode, inhibit discharge of the first bias voltage on the gate input of the first PMOS device when the sideband voltage signal exceeds the supply voltage

Clause 4: The apparatus of any preceding clause, wherein the or each feedthrough switch further comprises: a PMOS passthrough voltage follower circuit coupled to the supply voltage and to the input node and configured to, in a passthrough mode in which the sideband voltage signal is transmitted via the sideband channel, provide third and fourth level-shifted bias voltages to the gate inputs of the two PMOS devices, the level-shifted bias voltages tracking the sideband voltage signal according to a voltage offset to maintain the two PMOS devices in a conductive state for a first portion of a sideband voltage signal range.

Clause 5: The apparatus of any preceding clause, wherein the or each feedthrough switch further comprises: a NMOS device coupled in parallel with the cascode circuit; and a NMOS blocking voltage follower circuit coupled to the supply voltage and to the input node and configured, in the blocking mode, to provide a first NMOS level-shifted bias voltage to a gate input of the NMOS device, the first NMOS level-shifted bias voltage tracking the sideband voltage signal according to a voltage offset to maintain the NMOS device in a non-conductive state.

Clause 6: The apparatus of clause 5, wherein the or each feedthrough switch further comprises: a NMOS passthrough voltage follower circuit coupled to the supply voltage and to the input node and configured to, in a passthrough mode in which the sideband voltage signal is transmitted via the sideband channel, provide a second NMOS level-shifted bias voltage to the gate input of the NMOS device, the second NMOS level-shifted bias voltage tracking the sideband voltage signal according to a voltage offset to maintain the NMOS device in a conductive state for a second portion of the sideband voltage signal range.

Clause 7: The apparatus of clause 6, wherein the first portion of the sideband voltage signal range partially overlaps the second portion of the sideband voltage signal range, and wherein the first portion of the sideband voltage signal range and the second portion of the sideband voltage signal range collectively span all of the sideband voltage signal range, and wherein a minimum voltage of the first portion of the sideband voltage signal range is greater than a minimum voltage of the second portion of the sideband voltage signal range.

Clause 8: The apparatus of any preceding clause, wherein the PMOS blocking voltage follower circuit further comprises a voltage divider coupled to the supply voltage and having first and second nodes, and wherein the first and second level-shifted bias voltages are provided from the first and second nodes, respectively.

Clause 9: The apparatus of clause 8, wherein a minimum voltage of the first level-shifted bias voltage is lower than a minimum voltage of the second level-shifted bias voltage.

Clause 10: The apparatus of any preceding clause, wherein the overstress prevention voltage supply is configured to set the fixed voltage to a value that is between a maximum voltage of the sideband voltage signal and a minimum voltage of the sideband voltage signal.

Clause 11: The apparatus of clause 10, wherein the overstress prevention voltage supply is configured to set the fixed voltage to a value that is less than or equal to the difference between a maximum rated gate to source voltage of the first PMOS device and a minimum voltage of the sideband voltage signal and also greater than or equal to a difference between a maximum voltage of the sideband voltage signal and the maximum rated gate to source voltage of the first PMOS device.

Clause 12: A method, comprising: receiving, at one of a SBU input pin and a SBU output pin, a sideband voltage signal, the SBU input pin coupled to a SBU output pin via a feedthrough path; in a blocking mode, preventing the sideband voltage signal from being transmitted between the SBU input pin and the SBU output pin via the feedthrough path using two feedthrough switches that are each coupled in the feedthrough path between the SBU input pin and the SBU output pin, each feedthrough switch blocking the sideband voltage signal by: receiving the sideband voltage signal at a source of a first PMOS device that is part of a cascode circuit of the respective feedthrough switch, the cascode circuit comprising the first PMOS device and a second PMOS device connected in series between an input node and a center node, the input node coupled to one of the SBU input pin and the SBU output pin; biasing the cascode circuit by: providing, by a PMOS blocking voltage follower circuit of the respective feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage; and biasing the center node with a fixed voltage provided by an overstress prevention voltage supply.

Clause 13: A method, comprising: receiving, at one of a SBU input pin and a SBU output pin, a sideband voltage signal, the SBU input pin coupled to a SBU output pin via a feedthrough path; in a blocking mode, preventing the sideband voltage signal from being transmitted between the SBU input pin and the SBU output pin via the feedthrough path using a feedthrough switch that is coupled in the feedthrough path between the SBU input pin and the SBU output pin, the feedthrough switch blocking the sideband voltage signal by: receiving the sideband voltage signal at a source of a first PMOS device that is part of a cascode circuit of the feedthrough switch, the cascode circuit comprising the first PMOS device and a second PMOS device connected in series between an input node and a center node, the input node coupled to one of the SBU input pin and the SBU output pin; biasing the cascode circuit by: providing, by a PMOS blocking voltage follower circuit of the feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage; and biasing the center node with a fixed voltage provided by an overstress prevention voltage supply.

Clause 14: The method of clause 12 or clause 13, wherein preventing the sideband voltage signal from being transmitted between the SBU input pin and the SBU output pin via the feedthrough path further comprises capacitively coupling a gate of the first PMOS device to the sideband voltage signal by using a first bias current blocking circuit to inhibit discharge of the first bias voltage on the gate input of the first PMOS when the sideband voltage signal exceeds the supply voltage.

Clause 15: The method of any one of clauses 12 to 14, further comprising, in a passthrough mode, allowing the sideband voltage signal to be transmitted between the SBU input pin and the SBU output pin via the feedthrough path by: providing, by a PMOS passthrough voltage follower circuit coupled to the supply voltage and to the input node, third and fourth level-shifted bias voltages to the gate inputs of the two PMOS devices, the level-shifted bias voltages tracking the sideband voltage signal according to a voltage offset to maintain the two PMOS devices in a conductive state for a first portion of a sideband voltage signal range.

Clause 16: The method of any one of clauses 12 to 15, wherein the or each feedthrough switch further comprises an NMOS device coupled in parallel with the cascode circuit, the method further comprising, in the blocking mode: providing, by a NMOS blocking voltage follower circuit coupled to the supply voltage and to the input node, a first NMOS level-shifted bias voltage to a gate input of the NMOS device, the first NMOS level-shifted bias voltage tracking the sideband voltage signal according to a voltage offset to maintain the NMOS device in a non-conductive state.

Clause 17: The method of clause 16, wherein the or each feedthrough switch further comprises a NMOS passthrough voltage follower circuit coupled to the supply voltage and to the first node, the method further comprising, in a passthrough mode in which the sideband voltage signal is transmitted via the sideband channel: providing a second NMOS level-shifted bias voltage to the gate input of the NMOS device, the second NMOS level-shifted bias voltage tracking the sideband voltage signal according to a voltage offset to maintain the NMOS device in a conductive state for a second portion of the sideband voltage signal range.

Clause 18: The method of clause 17, wherein the first portion of the sideband voltage signal range partially overlaps the second portion of the sideband voltage signal range, and wherein the first portion of the sideband voltage signal range and the second portion of the sideband voltage signal range collectively span all of the sideband voltage signal range, and wherein a minimum voltage of the first portion of the sideband voltage signal range is greater than a minimum voltage of the second portion of the sideband voltage signal range.

Clause 19: The method of any one of clauses 12 to 18, further comprising providing the first and second level-shifted bias voltages from first and second nodes, respectively, of a voltage divider coupled to the supply voltage.

Clause 20: The method of clause 19, wherein a minimum voltage of the first level-shifted bias voltage is lower than a minimum voltage of the second level-shifted bias voltage.

Clause 21: The method of any one of clauses 12 to 19, further comprising the overstress prevention voltage supply setting the fixed voltage to a value that is between a maximum voltage of the sideband voltage signal and a minimum voltage of the sideband voltage signal.

Clause 22: The method of clause 21, further comprising the overstress prevention voltage supply setting the fixed voltage to a value that is less than or equal to the difference between a maximum rated gate to source voltage of the first PMOS device and a minimum voltage of the sideband voltage signal and also greater than or equal to a difference between a maximum voltage of the sideband voltage signal and the maximum rated gate to source voltage of the first PMOS device.

### Increasing Input Voltage Tolerance of Feedthrough Switch

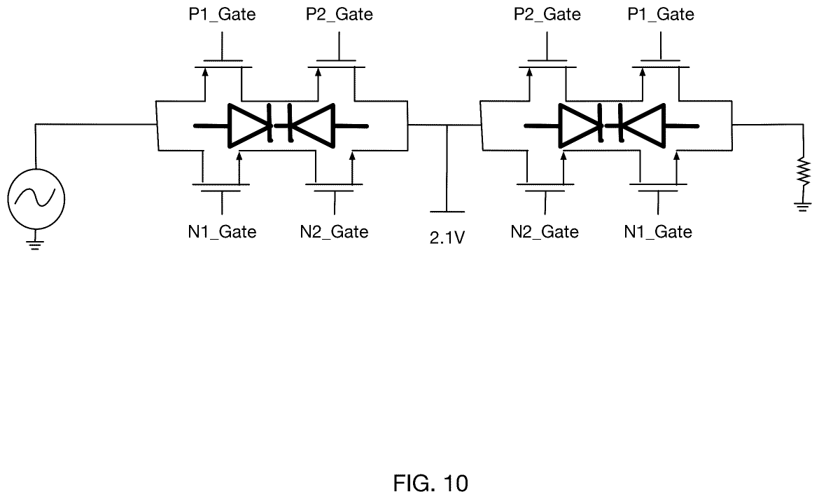

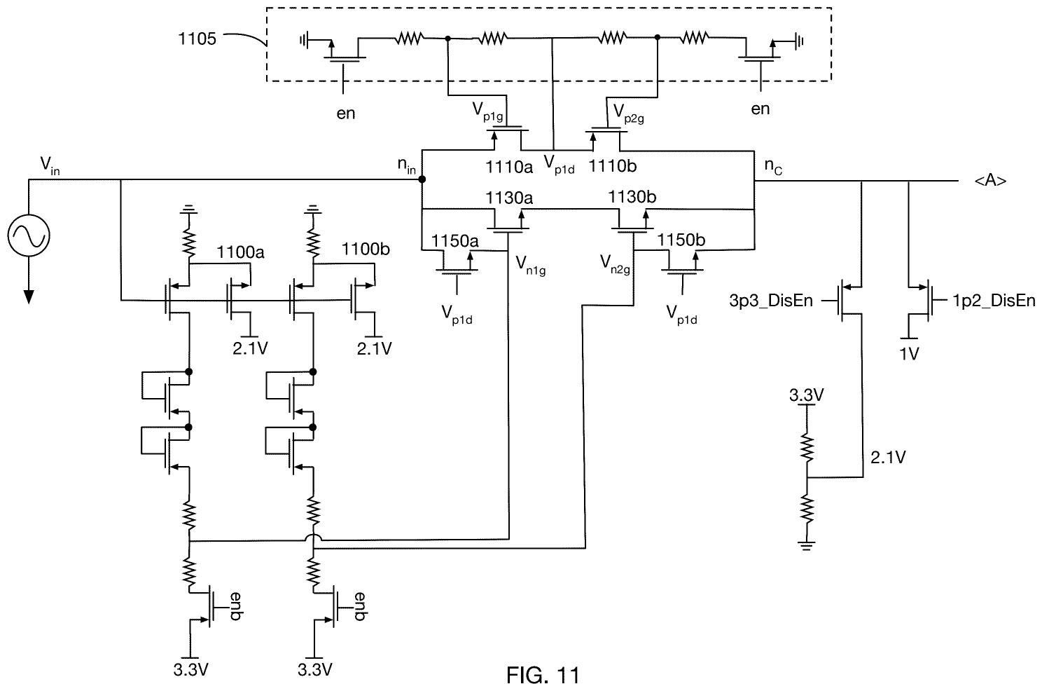

Designs may face aging and reliability concerns, and thus it may be beneficial to design a feed-through switch configured to tolerate a larger range of input voltages at either end of the switch. FIG. 10 illustrates a feedthrough switch having an increased tolerance for a range of input voltages, in accordance with some embodiments. As described above, transistor elements experience adverse effects when operated outside of their recommended voltage range. For example, applying a voltage input exceeding e.g., 2.1 volts may overdrive the transistors causing a large amount of leakage current, thus increasing power consumption. Furthermore, such effects may cause crosstalk to occur between input and output pins if sufficient isolation is not met. The design of FIG. 10 utilizes two CMOS in each set of pass gates, and the pair of CMOS in each of the NMOS and PMOS paths are configured to operate as back-to-back diodes. It is also noted that FIG. 10 illustrates the center node biased by 2.1V. If the operating threshold of a given transistor is 2.1V, then the input voltage swing tolerated by the feedthrough switch is 4.2V-exceeding the 3.73 volt threshold previously described. The variations of the feedthrough switch design are highlighted below with respect to FIG. 11.

FIG. 11 illustrates one half, e.g., the left half of the feed-through switch shown in FIG. 10. As shown, the PMOS pass gates are biased using 1105 to operate as short circuits when feed-through is enabled, and to operate as back-to-back diodes when feed-through is disabled. In the PMOS path, a voltage divider circuit with an enable switch is utilized to maintain the OFF/ON conditions of the device within maximum device stress voltages. During feed-through disable, enable switches are off and there is no current flowing through resistors, they simply act as short wires. During feed-through disable, one of the PMOS pass transistors is turned on to provide a voltage to the intermediate node between the PMOS pass transistors. This voltage on the intermediate node is felt at the gate of the other PMOS pass transistor to ensure the other PMOS pass transistor remains off. Specifically, at 0V, the source of PMOS 1110b corresponds to the terminal connected to the center node while the drain corresponds to the terminal connected to the intermediate node between the two PMOS. For PMOS 1110a, the terminal connected to the intermediate node is the source and the terminal connected to the input node is the drain. When the input voltage is 0V, the PMOS 1110b is enabled, connecting the 2.1V center node voltage to the intermediate node between the two PMOS 1110a/1110b. This 2.1V is felt at the gate of PMOS 1110a, ensuring that V_{gs}=0, and thus 1110a remains off. As the input voltage rises above 2.1V, the roles of the diodes reverse, i.e., 1110a turns on and forces 1110b to turn off. As the input crosses 2.1V+Vₜₕ, 1110a turns on, and the intermediate node begins tracking the input voltage. The input voltage is thus felt at the gate of 1110b, and V_{gs} of 1110b=0, and thus 1110b remains off.

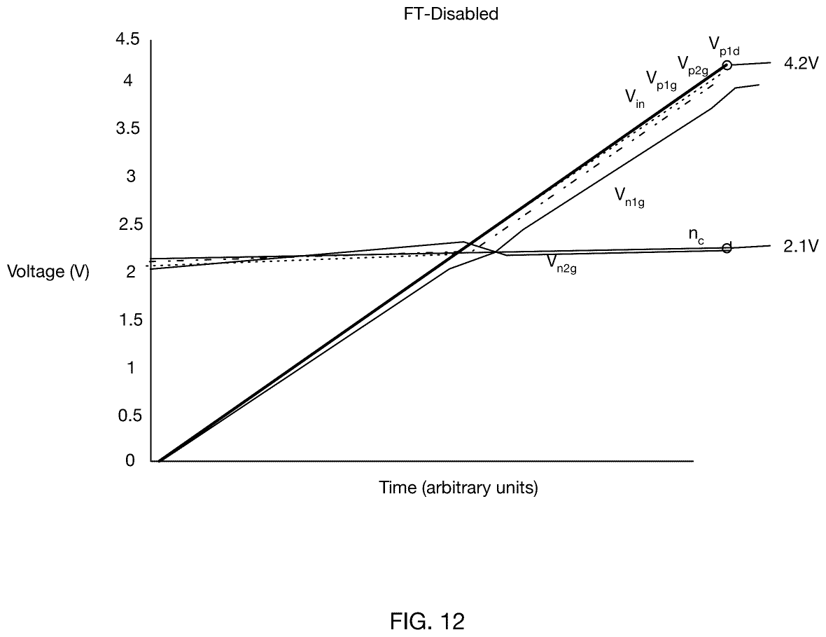

The NMOS path utilizes a similar principle to configure pass transistors 1130a and 1130b to operate in back-to-back diode configurations during the feed-through disable mode. As shown, extra NMOS switches 1150a and 1150b are included to configure the NMOS path in the back-to-back diode configuration by shorting the pass gate's source/drain to its gate. The transistors 1150a and 1150b receive the voltage V_{1pd} at their gates. Since Pld is always ≥max (Input or 2.1V), V_{pld} ensures 1150a and 1150b remain on and ensures the NMOS pass gate's source/drain are shorted to the gate. Specifically, V_{1pd} shorts Gate and Source of the OFF transistor among the NMOS pass gates, though the ON device sees a voltage of V_{pld}−Vₜₕ at its gate. In any case, the current is blocked because of the OFF-transistor in series. This can be seen the FIG. 12, where V_{n1g} follows the input voltage Vᵢₙ until 2.1V and when the role of the OFF switch is handed over to 1130b, Vₙ₂g corresponds to the center voltage of 2.1V. When the input voltage is 0V, the 2.1V on the center node is felt at the gate of 1130b, and 1130b is on, while 1130a is blocking. As the input voltage crosses 2.1V+Vₜₕ, 1130a turns on, while 1130b becomes blocking.

During feed-through enable mode, the enable transistors in the voltage divider 1105 are enabled, thus enabling the voltage divider. Thus, a voltage Vᵢₙ seen at the input node is provided to the intermediate node V_{pld}. The resistors have equal magnitude (and are large enough to ensure small leakage current), and thus a voltage of ½Vᵢₙ is seen at the gates of both PMOS 1110a and 1110b, ensuring they remain on. It is noted again that for the lower range of input signals, the PMOS pass gates start off, while the NMOS pass gates are enabled to pass the signal through. At the higher end of the input voltage range, the NMOS pass gates turn off while the PMOS pass gates remain on, similar to the designs described above. The NMOS path utilizes a similar PMOS source follower as previously described, with the addition of transistors 1100a and 1100b, which bias the sources of the source followers to 2.1V to prevent overdrive on the source follower branches, specifically when the input voltage reaches higher limits such as 4.2V. The source follower circuit is used to generate gate voltages higher than the input signal such that the NMOS pass gates remain on.

FIG. 12 is a waveform illustrating the various voltages discussed above as the input voltage is swept from 0V to 4.2V during a feedthrough-disabled mode. When the input voltage is at 0V, then the PMOS pass gate 1110b is enabled, which connects the center voltage 2.1V to the node V_{pld}. V_{pld} being 2.1V ensures that the PMOS pass gate 1110a remains off. When the input voltage Vᵢₙ reaches 2.1V, the roles of 1110a and 1110b reverse, i.e., 1110a turns on and the voltage V_{pld} begins to track the input voltage. V_{pld} tracking the input voltage ensures that 1110b due to the V_{gs} of 1110b being 0. Further, as the enable switches in 1105 are disabled, no current flows and thus the voltages V_{p1g} and V_{p2g} track the voltage V_{pld} as well, as illustrated in FIG. 12. For the NMOS voltages, the V_{n1g} follows the input voltage until Vᵢₙ crosses 2.1V, and the role of the off-switch is handed from 1130a to 1130b. At this point, the voltage V_{n1g} follows the input voltage (minus a Vₜₕ voltage drop from 1150a), while Vₙ₂g matches the center voltage 2.1V, ensuring that 1130b remains off.

In the designs described with respect to FIG. 4C, the node V_{pld} rose with the input voltage but was ultimately limited by the 3.3V supply. Thus, in scenarios in which the input voltage rose to e.g., 4.2V, the PMOS gates 410a and 410b switch on during feed-through disable mode, causing a leakage in current. Utilizing the diode configuration of FIG. 11, the voltage V_{pld} on the intermediate node rises with the input voltage and is no longer bounded by the 3.3V supply. For any given input voltage, one of the PMOS gates 1110a and 1110b remains in a current blocking state. As the input voltage rises to e.g., 4.2V, surpassing the supply voltage, the voltage V_{p1d} follows the input voltage, thus ensuring the PMOS transistor 1110b remains in the current blocking state. Table I below illustrates the performance difference for the designs of FIGS. 4C and 11:

TABLE I

| Parameter | FIG. 4C | FIG. 11 | Spec | Comments |
|---|---|---|---|---|
| Leakage @ 0 V | 7 nA | 157 nA | <400 nA | FT Disabled |
| input | | | | |
| Leakage @ 2.4 V | 45 nA | 50.7 nA | <25 uA | FT Disabled |
| input | | | | |
| Leakage @ 4.2 V | 116 uA | 1.79 uA | | FT Disabled |
| input | | | | |
| Input to Output | 64 dB | 67 dB | | FT Disabled, |
| Isolation | | | | with input |
| | | | | edge rate |
| | | | | 3.5 ns |
| Impedance | 12.2 Ω | 15.9 Ω | <17 Ω | FT Enabled, |
| | | | | Rₒₙ across |
| | | | | 0 to 3.73 V |
| Power | 20 uA | 39 uA | | FT Disabled, |
| | (66 uW) | (128 uW) | | current drawn |
| | | | | from 3.3 V |
| | | | | supply |

As shown in the table the design of FIG. 11 significantly reduces the leakage current in the presence of a 4.2V input and has an increased input to output isolation, with the tradeoff of consuming slightly more power, having slightly larger input resistance (while maintaining within the 17Ω spec), and slightly higher leakage currents at the 0 and 2.4V inputs (while still conforming within the spec).

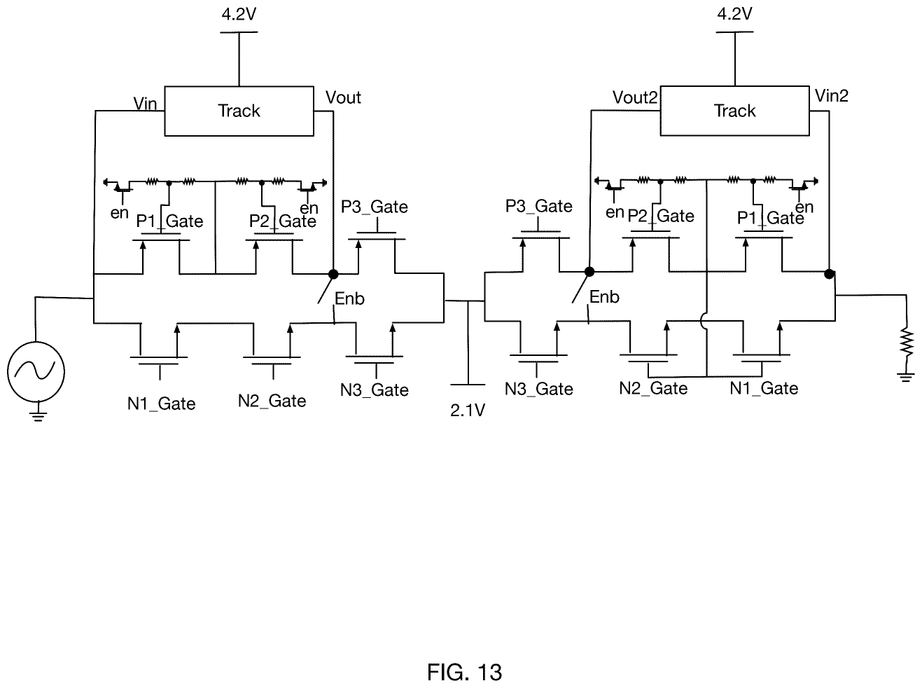

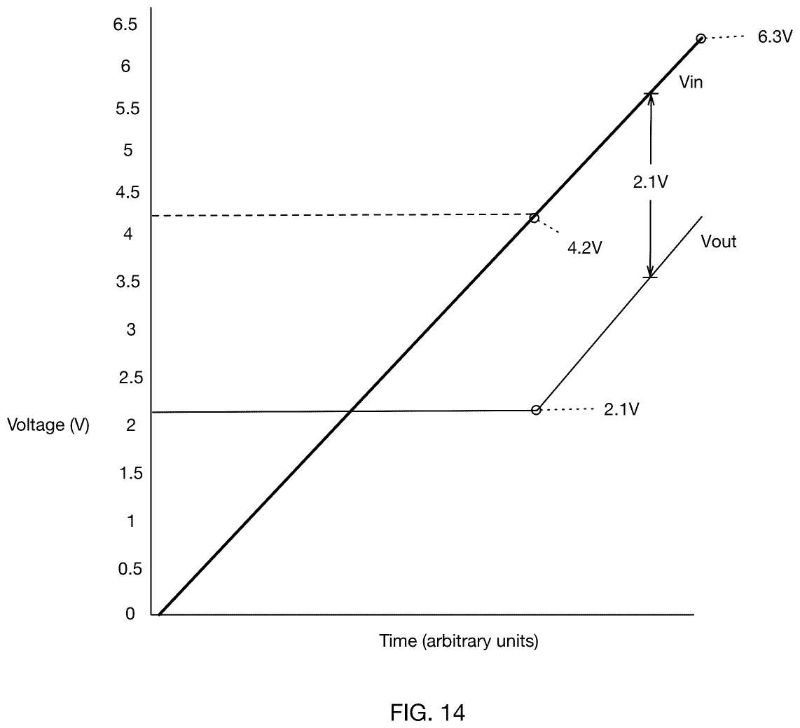

FIG. 13 illustrates an embodiment for further extending the input voltage range is shown. The embodiment of FIG. 13 is similar to the embodiments previously described, with the addition of a third transistor in each set of pass gates coupled in series to the original two. The node between the second and third stages of the pass gates is biased using an output voltage “Vout” of a tracking circuit to ensure that the CMOS pass gates do not experience overdrive stress voltages across their terminals. The operation of the tracking circuit is illustrated in FIG. 14. Specifically, when the input voltage Vᵢₙ is at a minimum, 0V, the output of the tracking circuit is 2.1V to ensure that the CMOS devices do not experience a voltage across their terminals that exceeds 2.1V. As the Vᵢₙ increases, the voltage Vout remains at 2.1V until the input voltage reaches 4.2V. As Vᵢₙ surpasses 4.2V, the output voltage Vout increases to maintain a 2.1V voltage difference from Vᵢₙ. As Vᵢₙ reaches 6.3V, the output voltage Vout reaches 4.2V. Depending on the constraints of the design, additional stages of the feedthrough switch may be added by including additional pass gates to extend the operating range, provided that the design continues to fall within the design specifications such as power, on resistance, etc.

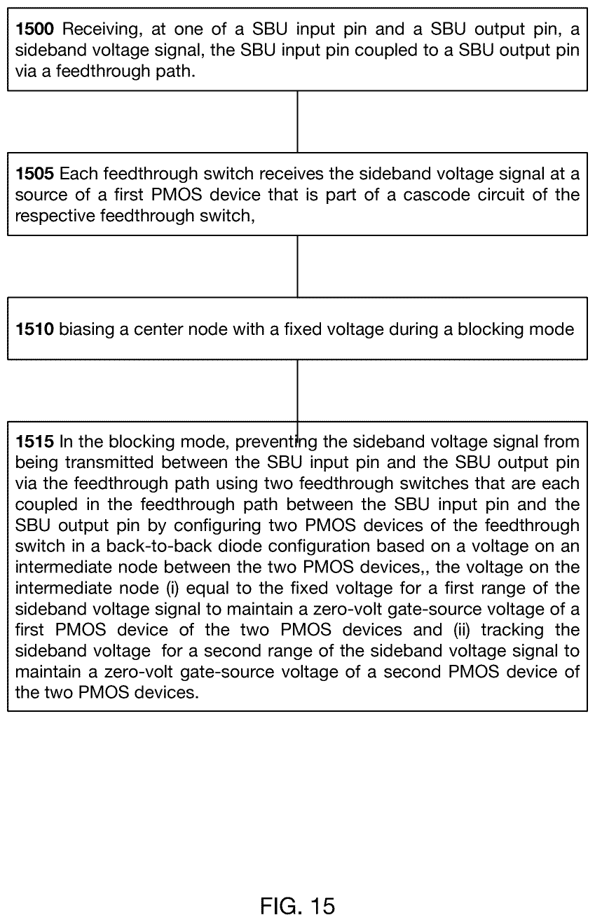

FIG. 15 is a flowchart of a method, in accordance with some embodiments. The method of FIG. 15 includes receiving 1500, at one of a SBU input pin and a SBU output pin, a sideband voltage signal, the SBU input pin coupled to a SBU output pin via a feedthrough path. The method further includes receiving 1505, at each feedthrough switch, the sideband voltage signal at a source of a first PMOS device of two PMOS devices that are part of a cascode circuit. The method further includes biasing 1510 a center node with a. fixed voltage during a blocking mode. The method further includes preventing 1515, in the blocking mode, the sideband voltage signal from being transmitted between the SBU input pin and the SBU output pin via the feedthrough path using the two feedthrough switches. In some embodiments, preventing 1515 the sideband voltage signal from being transmitted between the SBU input pin and the SBU output pin includes configuring the two PMOS devices in a back-to-back diode configuration during the blocking mode based on a voltage on an intermediate node between the two PMOS devices, the voltage on the intermediate node (i) equal to the fixed voltage for a first range of the sideband voltage signal to maintain a zero-volt gate-source voltage of a first PMOS device of the two PMOS devices and (ii) tracking the sideband voltage for a second range of the sideband voltage signal to maintain a zero-volt gate-source voltage of a second PMOS device of the two PMOS devices.

1. An apparatus, comprising:
two feedthrough switches coupled in a feedthrough path between a sideband use (SBU) input pin and a SBU output pin and configured, in a blocking mode, to prevent a sideband voltage signal from being transmitted between the SBU input pin and the SBU output pin via the feedthrough path, each feedthrough switch comprising:
an overstress prevention voltage supply configured to, in the blocking mode, bias the center node with a fixed voltage;
a cascode circuit comprising two PMOS devices connected in series between an input node and a center node, and two NMOS devices connected in series between the input node and the center node, the two NMOS devices connected in parallel to the two PMOS devices, the input node coupled to a respective one of the SBU input pin and the SBU output pin and configured to receive the sideband voltage signal at a source of a first PMOS device of the two PMOS devices;
the two PMOS devices configured in a back-to-back diode configuration during the blocking mode based on a voltage on an intermediate node between the two PMOS devices, the voltage on the intermediate node (i) equal to the fixed voltage for a first range of the sideband voltage signal to maintain a zero-volt gate-source voltage of a first PMOS device of the two PMOS devices and (ii) tracking the sideband voltage for a second range of the sideband voltage signal to maintain a zero-volt gate-source voltage of a second PMOS device of the two PMOS devices.

2. The apparatus of claim 1, further comprising two NMOS switches to configure the two NMOS devices in a back-to-back diode configuration during the blocking mode, the two NMOS switches configured to receive the voltage on the intermediate node, and wherein a first NMOS switch of the two NMOS switches configures a first of the two NMOS devices with a zero-volt gate-source voltage for a first range of the sideband voltage signal, and a second NMOS of the two NMOS switches configures a second of the two NMOS devices with the zero-volt gate-source voltage for a second range of the sideband voltage signal.

3. The apparatus of claim 1, further comprising a voltage divider circuit enabled during a passthrough mode, the voltage divider configured to receive the voltage on the intermediate node and to generate a gate voltage for the two PMOS devices sufficient for the two PMOS devices to remain in a conducting state.

4. The apparatus of claim 1, wherein each feedthrough switch further comprises:
a NMOS passthrough voltage follower circuit coupled to the supply voltage and to the input node and configured to, in a passthrough mode in which the sideband voltage signal is transmitted via the sideband channel, provide a second NMOS level-shifted bias voltage to the gate input of the NMOS device, the second NMOS level-shifted bias voltage tracking the sideband voltage signal according to a voltage offset to maintain the NMOS device in a conductive state for a second portion of the sideband voltage signal range.

5. The apparatus of claim 4, wherein the NMOS passthrough voltage follower circuit further includes a second overstress prevention circuit configured to bias the NMOS passthrough voltage follower circuit with an overdrive prevention voltage to ensure no CMOS devices in the NMOS passthrough voltage follower circuit experience an overdrive voltage.

6. The apparatus of claim 5, wherein the overdrive prevention voltage is equal to the center node voltage.

7. The apparatus of claim 1, wherein each feedthrough switch further comprises a third PMOS device connected in series to the two PMOS devices of the cascode circuit.

8. The apparatus of claim 7, further comprising a voltage input tracking circuit configured to bias a second intermediate voltage node between the third PMOS device and a respective one of the two PMOS devices.

9. The apparatus of claim 8, wherein each feedthrough switch further comprises a third NMOS device connected in series to the two NMOS devices of the cascode circuit.

10. The apparatus of claim 9, wherein the voltage input tracking circuit is further configured to bias a third intermediate voltage node between the third NMOS device and a respective one of the two NMOS devices.

11. A method, comprising:
receiving, at one of a SBU input pin and a SBU output pin, a sideband voltage signal, the SBU input pin coupled to a SBU output pin via a feedthrough path;
in a blocking mode, preventing the sideband voltage signal from being transmitted between the SBU input pin and the SBU output pin via the feedthrough path using two feedthrough switches that are each coupled in the feedthrough path between the SBU input pin and the SBU output pin, each feedthrough switch blocking the sideband voltage signal by:
receiving the sideband voltage signal at a source of a first PMOS device that is part of a cascode circuit of the respective feedthrough switch, the cascode circuit comprising the first PMOS device and a second PMOS device connected in series between an input node and a center node, the input node coupled to one of the SBU input pin and the SBU output pin;
biasing the cascode circuit by:
providing, by a PMOS blocking voltage follower circuit of the respective feedthrough switch that is coupled to a supply voltage and to the input node, first and second level-shifted bias voltages to respective gate inputs of the first PMOS device and the second PMOS device, the level-shifted bias voltages tracking the sideband voltage signal according to a voltage offset to maintain the two PMOS devices in a non-conductive state while the sideband voltage signal is below the supply voltage; and
biasing the center node with a fixed voltage provided by an overstress prevention voltage supply.

12. The method of claim 11, wherein preventing the sideband voltage signal from being transmitted between the SBU input pin and the SBU output pin via the feedthrough path further comprises capacitively coupling a gate of the first PMOS device to the sideband voltage signal by using a first bias current blocking circuit to inhibit discharge of the first bias voltage on the gate input of the first PMOS when the sideband voltage signal exceeds the supply voltage.

13. The method of claim 11, further comprising, in a passthrough mode, allowing the sideband voltage signal to be transmitted between the SBU input pin and the SBU output pin via the feedthrough path by:
providing, by a PMOS passthrough voltage follower circuit coupled to the supply voltage and to the input node, third and fourth level-shifted bias voltages to the gate inputs of the two PMOS devices, the level-shifted bias voltages tracking the sideband voltage signal according to a voltage offset to maintain the two PMOS devices in a conductive state for a first portion of a sideband voltage signal range.

14. The method of claim 11, wherein each feedthrough switch further comprises an NMOS device coupled in parallel with the cascode circuit, the method further comprising, in the blocking mode:
providing, by a NMOS blocking voltage follower circuit coupled to the supply voltage and to the input node, a first NMOS level-shifted bias voltage to a gate input of the NMOS device, the first NMOS level-shifted bias voltage tracking the sideband voltage signal according to a voltage offset to maintain the NMOS device in a non-conductive state.

15. The method of claim 14, wherein each feedthrough switch further comprises a NMOS passthrough voltage follower circuit coupled to the supply voltage and to the first node, the method further comprising, in a passthrough mode in which the sideband voltage signal is transmitted via the sideband channel:
providing a second NMOS level-shifted bias voltage to the gate input of the NMOS device, the second NMOS level-shifted bias voltage tracking the sideband voltage signal according to a voltage offset to maintain the NMOS device in a conductive state for a second portion of the sideband voltage signal range.

16. The method of claim 15, wherein the first portion of the sideband voltage signal range partially overlaps the second portion of the sideband voltage signal range, and wherein the first portion of the sideband voltage signal range and the second portion of the sideband voltage signal range collectively span all of the sideband voltage signal range, and wherein a minimum voltage of the first portion of the sideband voltage signal range is greater than a minimum voltage of the second portion of the sideband voltage signal range.

17. The method of claim 11, further comprising providing the first and second level-shifted bias voltages from first and second nodes, respectively, of a voltage divider coupled to the supply voltage.

18. The method of claim 17, wherein a minimum voltage of the first level-shifted bias voltage is lower than a minimum voltage of the second level-shifted bias voltage.

19. The method of claim 11, further comprising the overstress prevention voltage supply setting the fixed voltage to a value that is between a maximum voltage of the sideband voltage signal and a minimum voltage of the sideband voltage signal.

20. The method of claim 19, further comprising the overstress prevention voltage supply setting the fixed voltage to a value that is less than or equal to the difference between a maximum rated gate to source voltage of the first PMOS device and a minimum voltage of the sideband voltage signal and also greater than or equal to a difference between a maximum voltage of the sideband voltage signal and the maximum rated gate to source voltage of the first PMOS device.
